(19) United States
(12) Patent Application Publication
(10) Pub. No.: US 2013/0249542 A1
(43) Pub. Date: Sep. 26, 2013

(54) FOLDABLE SUBSTRATE

(71) Applicants: Yang Zhao, Andover, MA (US); Haidong Liu, Wuxi (CN); Yongyao Cai, Acton, MA (US); Zongya Li, Wuxi (CN); Noureddine Hawat, Wilmington, MA (US); Jun Ma, Suzhou (CN); Feng Zhang, Wuxi (CN); Zhiwei Duan, Wuxi (CN); Leyue Jiang, Wuxi (CN)

(72) Inventors: Yang Zhao, Andover, MA (US); Haidong Liu, Wuxi (CN); Yongyao Cai, Acton, MA (US); Zongya Li, Wuxi (CN); Noureddine Hawat, Wilmington, MA (US); Jun Ma, Suzhou (CN); Feng Zhang, Wuxi (CN); Zhiwei Duan, Wuxi (CN); Leyue Jiang, Wuxi (CN)

(21) Appl. No.: 13/426,341

(22) Filed: Mar. 21, 2012

(51) Int. Cl. G01R 33/02; H05K 1/18; B23P 17/04; B32B 3/16; B32B 7/04

(52) U.S. Cl. 324/244; 428/77; 29/416; 174/254

(57) ABSTRACT

A foldable substrate is provided that includes a first substrate portion with a first upper surface and a second substrate portion with a second upper surface. A foldable bridge portion couples the first substrate portion to the second substrate portion. The foldable bridge portion includes a coupling strip that extends from the first substrate portion to the second substrate portion with a gap corresponding to a portion of the coupling strip where the gap is defined between the first and second substrate portions by removing portions of a starting wafer substrate. The first and second portions, in one embodiment, include magnetic field sensors and the foldable bridge portion can be bent to arrange the two portions at a predetermined angle to one another. Once bent, the sensor package can be incorporated into a magnetic field sensor assembly to be integrated with other control circuitry.

### STATEMENT REGARDING FEDERALLY SPONSORED RESEARCH OR DEVELOPMENT

N/A

### BACKGROUND OF THE INVENTION

In many devices, for example, cellular phones, personal navigation devices, etc., sensing along an out of plane functional axis is required in an integrated package. These devices, however, are fabricated using semiconductor processes but because of the two dimensional nature of semiconductor processes, an out of plane structure is very difficult to produce. In many cases, therefore, MEMS, or other non-traditional fabrication processes, are employed. The use of such methods, however, make the device more expensive and require longer development cycles.

What is needed, therefore, is an accurate field sensor, e.g., a magnetic field sensor, that includes out of plane functionality, that is small in size, low in cost, and is easily incorporated into a device.

### BRIEF SUMMARY OF THE INVENTION

An embodiment of the present invention is directed to a foldable substrate comprising a first substrate portion having a first upper surface and a second substrate portion having a second upper surface. A foldable bridge portion couples the first substrate portion to the second substrate portion and the foldable bridge portion includes a coupling strip extending from the first substrate portion to the second substrate portion and a gap corresponding to a portion of the coupling strip and defined between the first and second substrate portions.

A method of manufacturing a foldable substrate includes providing a wafer substrate having a wafer body portion, an upper surface and a lower surface and defining a first substrate portion and a second substrate portion of the wafer substrate. A foldable bridge portion is provided to extend from the first substrate portion to the second substrate portion; and portions of the wafer body portion are removed to create a gap corresponding to at least a portion of the foldable bridge portion.

Further, a foldable substrate comprises a first substrate portion having a first upper surface and a first lower surface and a second substrate portion having a second upper surface and a second lower surface. A foldable portion couples the first substrate portion to the second substrate portion and comprises a flexible material attached to the first and second lower surfaces.

A method of manufacturing a foldable substrate includes providing a wafer having a body portion, an upper surface and a lower surface and providing one or more devices on the upper surface of the wafer. Each device comprises at least one zone free of circuitry extending in a direction from the upper surface down through the body portion. A flexible material is attached to the lower surface of the wafer at least under each device and each circuitry-free zone is removed from the top surface of the wafer through the wafer body portion and down to, but not removing, the flexible material.

### BRIEF DESCRIPTION OF THE SEVERAL VIEWS OF THE DRAWINGS

Embodiments of the present invention may be better understood by referring to the following description in conjunction with the accompanying drawings in which:

FIGS. 1A and 1B are schematic representations of devices on a wafer and a close-up of one of the devices, respectively;

FIG. 2 is a method in accordance with an embodiment of the present invention;

FIGS. 3A-3E are schematic representations of the stages of the manufacturing of a device in accordance with an embodiment of the present invention;

FIG. 4 is a schematic top view of the device of FIGS. 3A-3E;

FIGS. 5A-5C are schematic representations of the stages of manufacturing a magnetic field sensor assembly incorporating the magnetic field sensor of FIGS. 3A-3E;

FIG. 6 is a perspective view of an assembled magnetic field sensor assembly of FIGS. 3A-3E;

FIGS. 7A-7E are schematic representations of the stages of the manufacturing of a device in accordance with an embodiment of the present invention;

FIG. 8 is a schematic top view of the device of FIGS. 7A-7E;

FIGS. 9A-9D are schematic representations of manufacturing a magnetic field sensor assembly incorporating the magnetic field sensor of FIGS. 7A-7C;

FIG. 10 is a perspective view of an assembled magnetic field sensor assembly of FIGS. 7A-7E;

FIGS. 11A and 11B are, respectively, schematic top views of the embodiments shown in FIGS. 3A-3E and FIGS. 7A-7E;

FIGS. 12A and 12B are schematic representations of a variation of the embodiment of the present invention shown in FIGS. 5A-5C;

FIG. 13 is a schematic representation of another embodiment of the present invention providing sensor out of plane orientation;

FIGS. 14A and 14b are schematic representations of the embodiment of the present invention shown in FIG. 13 attached to a substrate;

FIGS. 15A and 15B are schematic representations of a variation of the embodiment of the present invention shown in FIGS. 3D and 3E including inter-silicon vias;

FIG. 16 is a schematic representation of the device of FIG. 15B installed in an assembly;

FIGS. 17A and 17B are schematic representations of a variation of the embodiment of the present invention shown in FIGS. 7D and 7E including inter-silicon vias;

FIG. 18 is a schematic representation of the device of FIG. 17B installed in an assembly;

FIG. 19 is a perspective view of the assembly of FIG. 18;

FIGS. 20A and 20B are schematic representations of devices, in accordance with another embodiment of the present invention, on a wafer and a close-up of one of the devices, respectively;

FIG. 21 is a method in accordance with another embodiment of the present invention;

FIGS. 22A-22C are schematic side-views of a device in accordance with an embodiment of the present invention;

FIG. 23 is a schematic representation of the device of FIGS. 22A-22C installed in an assembly.

FIGS. 24A-24C are schematic sideviews of a device in accordance with an embodiment of the present invention;

FIG. 25 is a schematic representation of the device of FIGS. 24A-24C in a right angle configuration;

FIG. 26 is a schematic representation of an embodiment of the present invention; and

FIG. 27 is a schematic representation of the device of FIG. 26 in a right angle configuration.

It will be appreciated that for simplicity and clarity of illustration, elements shown in the drawings have not necessarily been drawn accurately or to scale. For example, the dimensions of some of the elements may be exaggerated relative to other elements for clarity or several physical components may be included in one functional block or element. Further, where considered appropriate, reference numerals may be repeated among the drawings to indicate corresponding or analogous elements. Moreover, some of the blocks depicted in the drawings may be combined into a single function.

### DETAILED DESCRIPTION OF THE INVENTION

In the following detailed description, numerous specific details are set forth in order to provide a thorough understanding of the embodiments of the present invention. It will be understood by those of ordinary skill in the art that these embodiments of the present invention may be practiced without some of these specific details. In other instances, well-known methods, procedures, components and structures may not have been described in detail so as not to obscure the embodiments of the present invention.

Embodiments of the present invention include a magnetic field sensor based on anisotropic magnetoresistive (AMR) technology. As known, in an AMR device, thin film permalloy material is deposited on a silicon wafer while a strong magnetic field is applied to create permalloy resistors. The magnetic domains of these permalloy resistors are aligned in the same direction as the applied field thereby establishing a magnetization vector. Subsequent lithographic and etching steps define the geometry of the AMR resistors.

Prior to explaining at least one embodiment of the present invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein are for the purpose of description and should not be regarded as limiting. Further, the present invention is not limited to magnetic sensors or any other specific type of device.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

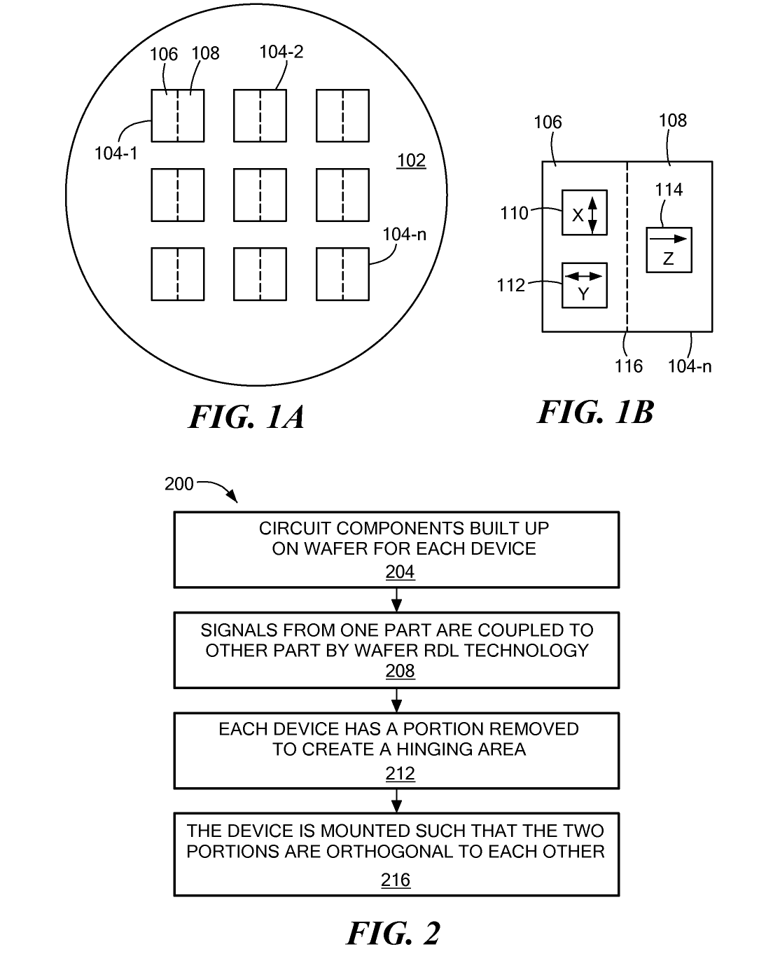

Generally, as is known to one of ordinary skill in the art, a wafer 102, as shown in FIG. 1A, is used as the basis on which a plurality of devices, e.g., magnetic field sensors 104-n, are provided. Usually, the wafer 102 is made from a semiconductor material, e.g., silicon, although the embodiments of the present invention are not limited thereto and other base materials may be used as is well known to those of ordinary skill in the art. As will be discussed in more detail below, in one embodiment of the present invention, each magnetic field sensor 104 includes a first portion 106 and a second portion 108.

Referring now to FIG. 1B, the first portion 106 may contain an X-axis magnetometer 110 and a Y-axis magnetometer 112 oriented with respect to each other in order to detect a magnetic field along a respective X, Y axis. The second portion 108 includes a Z-axis magnetometer 114. The Z-axis magnetometer 114 is oriented on the second portion 108 such that when the second portion 108 is oriented perpendicular to the first portion 106 along a virtual hinge 116, the magnetometer 104-n is then capable of detecting a magnetic field in all three axis X,Y,Z.

As an overview, a method 200, as shown in FIG. 2, starts at step 204 where the circuit components necessary to support a magnetometer or magnetic field sensor, for example, based on AMR technology, are built up on the wafer 102. As known to those of ordinary skill in the art, depending upon the size of the wafer 102 a plurality of such devices 104 may be provided. Well known processes such as lithography and thin film permalloy material deposition may be used to manufacture these devices. Subsequently, step 208, signal paths from the first portion 106 to the second portion 108 are coupled together by a hinging area or section, which will be described in more detail below, that may be created by using wafer redistribution layer (RDL) technology.

One of ordinary skill in the art will understand that RDL technology is usually used when referring to moving a wire bond pad. In the present invention, however, while bond pads are not necessarily being moved, the same RDL technology can be leveraged to couple the first and second portions.

As will be described in more detail below in one embodiment of a magnetic field sensor, each device 104-n is provided with a hinging area by having a portion of the wafer 102, and other material, removed from underneath, step 212. As part of a final process, the device 104-n is mounted such that the first portion 106 and the second portion 108 are orthogonal, i.e., perpendicular to one another, in order to establish the magnetic X, Y, Z axes orientation, step 216. Of course, it should be noted that the first and second portions need not necessarily be orthogonal to one another and any angle can be provided.

Thus, a substrate is manufactured from a single planar material and provided with the bridging or hinging area in order to allow for two portions to subsequently be arranged at a desired angle with respect to one another. The manufactured device is, therefore, bendable.

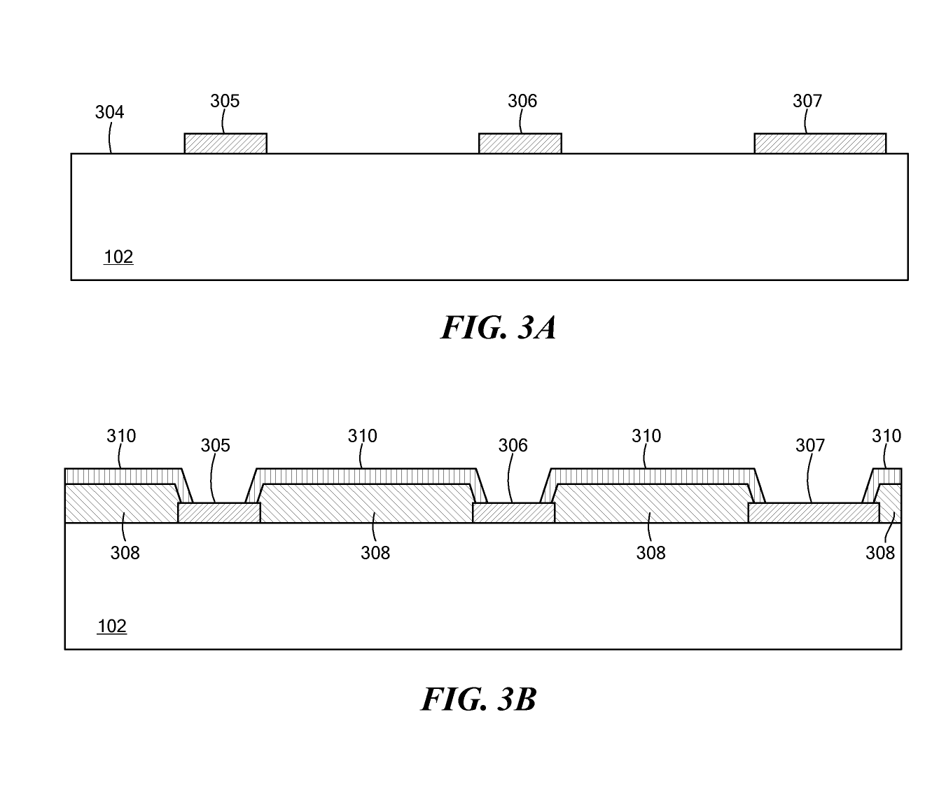

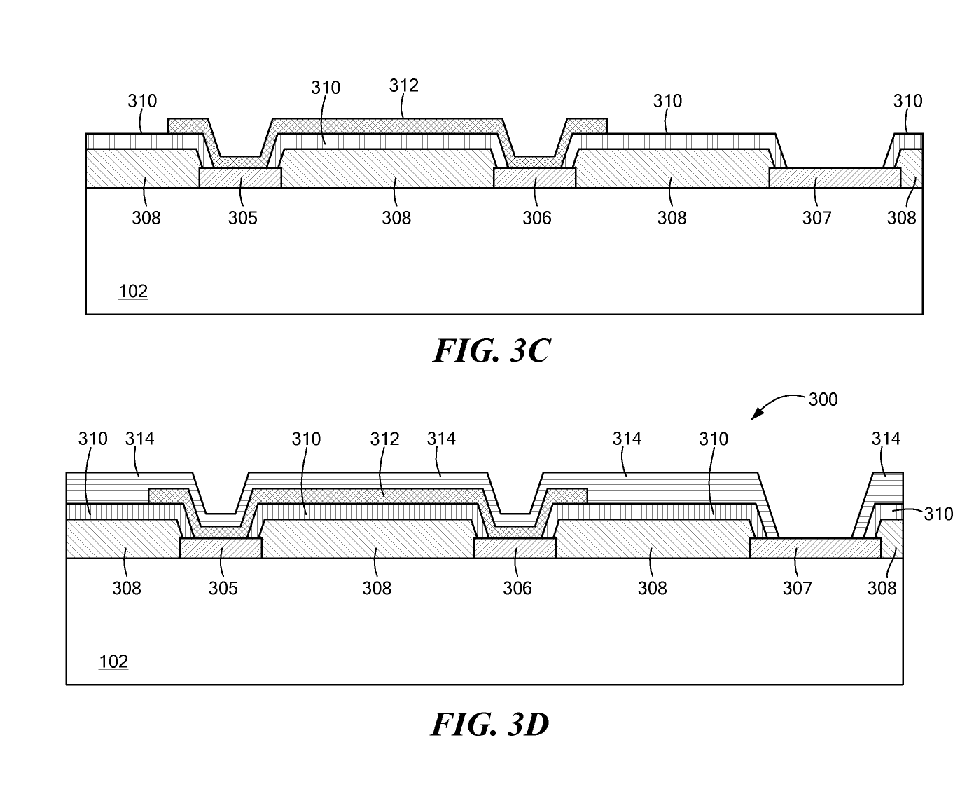

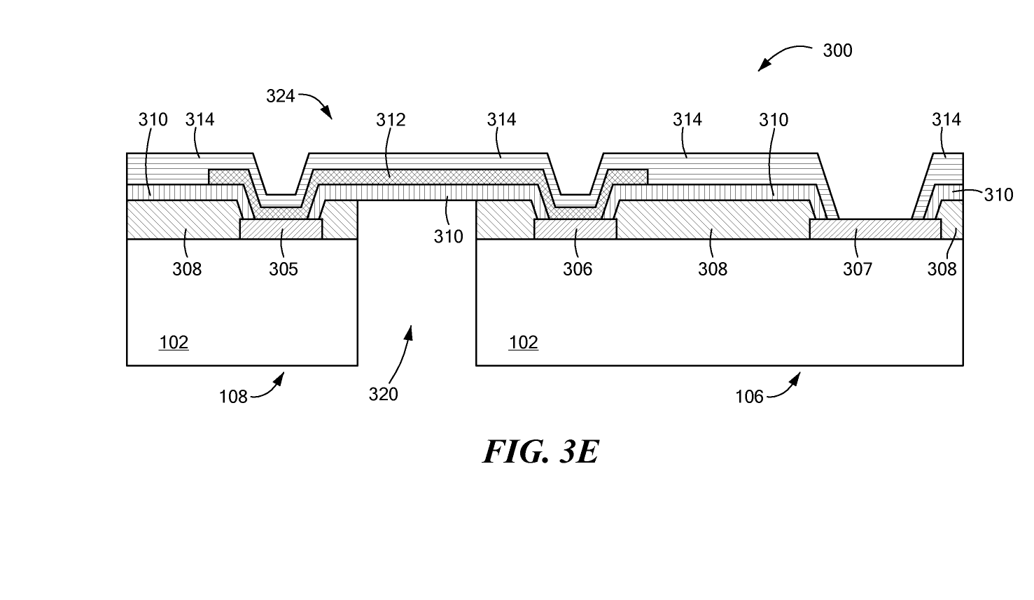

A wafer 102 having a lower surface 302 and an upper surface 304, as shown in FIG. 3A, is processed in accordance with known wafer processing techniques to create the circuitry necessary for creating a magnetic field sensor including first, second and third connection pads 305, 306 and 307, respectively, placed on the upper surface 302. These connection pads 305, 306 and 307 may be made from any one of a number of conductive metals, for example, copper, gold, silver, etc. Subsequently, a passivation layer 308 is deposited on the upper surface 304, as shown in FIG. 3B. The passivation layer 308, however, is configured such that a substantial portion of the connection pads 305, 306 and 307 are left exposed. Next, a lower insulating layer 310 is deposited over the passivation layer 308 but, similar to the deposition of the passivation layer 308, the connection pads 305, 306 and 307 are left exposed. It should be noted that there are a number of known techniques for assuring that any deposited layer does not cover any particular area. These processes include photo masking or etching, for example.

A coupling strip 312 is then provided which connects the connection pad 305 and the connection pad 306 to one another. Thus, these two connection pads 305, 306 are electrically coupled to one another by the coupling strip 312, as shown in FIG. 3C.

An upper insulating layer 314 is then deposited over the exposed portions of the lower insulating layer 310, and the coupling strip 312, as shown in FIG. 3D. The upper insulating layer 314, however, is configured such that it does not cover the third connection pad 307 which is, instead, left, effectively, exposed.

Once the wafer processing is completed, i.e., all of the layers or strips have been deposited to complete the manufacturing of the devices, and the wafer 102 has been through any other process steps, the devices 104-n must be cut away from the wafer 102 itself. In accordance with one embodiment of the present invention, however, prior to the individual device 104-n being cut from the wafer 102, a portion of each device 104-n is cut away to create a gap 320, as shown in FIG. 3E.

The gap 320 is located in that portion of the wafer 102 below, or corresponding to, the coupling strip 312 between the first connection pad 305 and the second connection pad 306. The gap 320 may be created in the wafer 102 for each device 104-n either by blade sawing, laser sawing or by an etching operation with appropriate masking. In any event, the wafer 102 is cut from the back surface 302 through the wafer 102 and through the passivation layer 308 leaving the lower insulating layer 310, the coupling strip 312 and the upper insulating layer 314 untouched. In addition, even the lower insulating layer 310, or a portion thereof, may be removed to create the gap 320. As a result, each device 104-n, as described above, has the first portion 106 coupled to the second portion 108 by a remaining part of the lower insulating layer 310, the coupling strip 312 and the upper insulating layer 314 to define a foldable bridge portion 324. The coupling strip 312 electrically couples, in this case, the first connection pad 305 to the second connection pad 306. Thus, any circuitry coupled to these respective connection pads are coupled through this coupling strip 312.

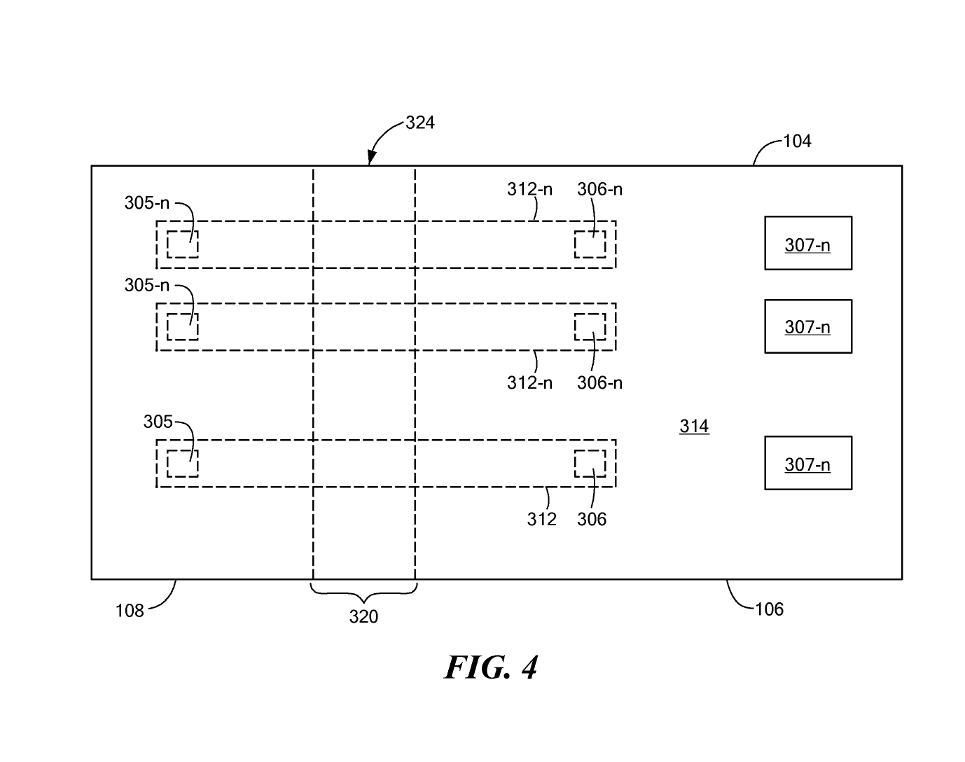

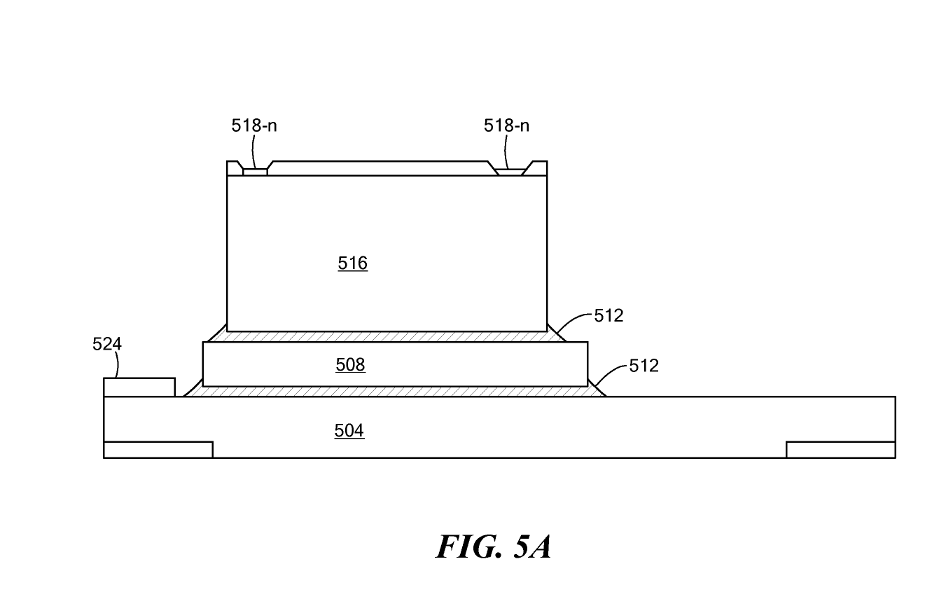

It should be noted that FIGS. 3A-3E represent a side view of the device and that there may be numerous other connection pads 305-n and 306-n also coupled from the first portion 106 to the second portion 108. Thus, referring to FIG. 4, a top view of a device, there is shown a number of connection pads 307-n similar to the third connection pad 307 that are exposed through the upper insulating layer 314 and a number of coupling strips 312-n below the upper insulating layer coupling connection pads 305-n on the first portion 106 to other connection pads 306-n on the second portion 108 across the gap 320. Thus, one of ordinary skill in the art will understand that the plurality of coupling strips 312-n are at a same level, in the build-up of circuitry layers, with one another.

As the device 300 is bendable by operation of the foldable bridge portion 324, those layers or strips in the foldable bridge portion 324 are of a thickness and/or material that facilitates being bendable without breaking. Such materials include, but are not limited to, metals, semiconductors, insulators, etc. One of ordinary skill in the art will understand that various materials, conductive and non-conductive, can be used in the foldable bridge portion 324 to provide the functionality described herein.

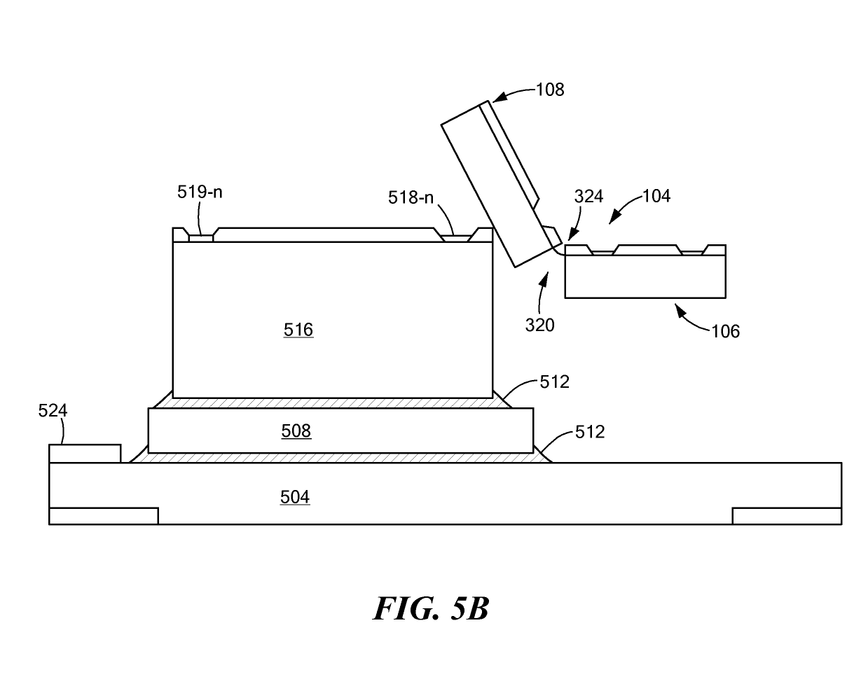

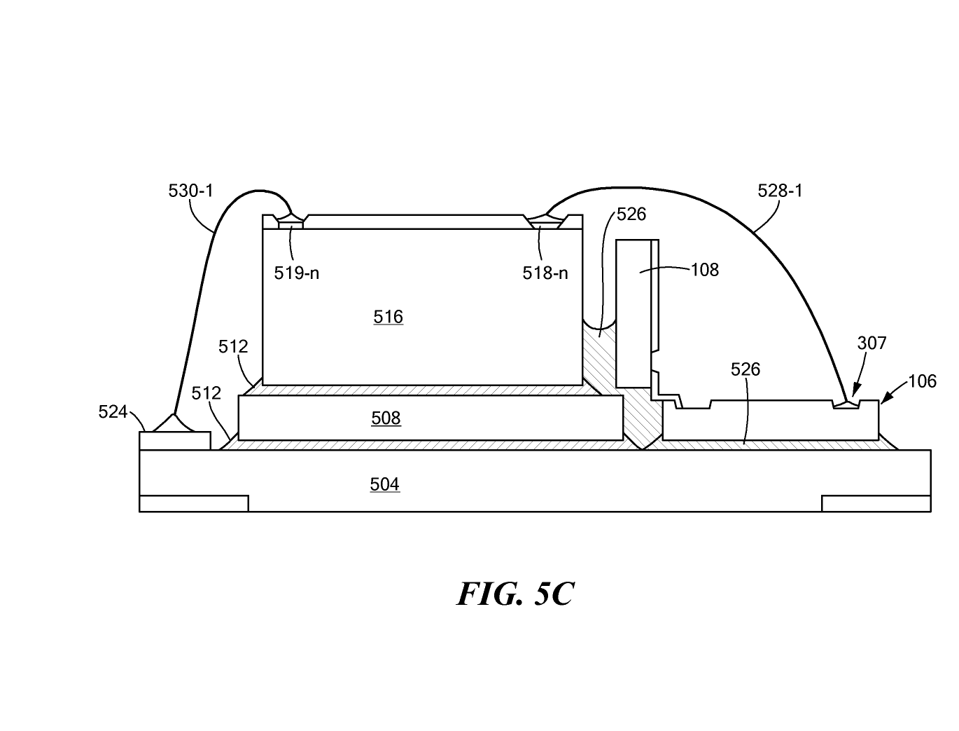

Once a device 104-n is separated from the wafer, it is then connected to additional circuitry, for example, an ASIC device, that will process the magnet field sensor outputs to create a magnetic field sensor assembly. Referring now to FIG. 5A, a printed circuit board (PCB) 504 is provided and a spacer 508, optionally, is attached to an upper surface of the PCB 504 using die attach processing 512. A base device 516 is attached to the spacer 508 by the same die attach processing 512. The base device 516 has a plurality of device contacts 518-n on its upper surface.

A magnetic field sensor device 104-n is positioned adjacent the spacer 508 and the base device 516 such that the second portion 108 of the device 104 is perpendicular to the first portion 106. Referring to FIG. 5B, the magnetic field sensor device 104 may be positioned by being picked, for example, by a “pick and place” device, or by a die bonder directly and placed onto the PCB 504 such that the second portion 108 is displaced when contacting the base device 516 as shown. The flexibility of the foldable bridge portion 324 allows the second portion 108 to bend with respect to the first portion 106.

Subsequently, the first portion 106 and the second portion 108 are attached to the PCB 504 and/or the base device 516 by using epoxy or underfill 526, as shown in FIG. 5C, to maintain the orthogonality between the first portion 106 and the second portion 108.

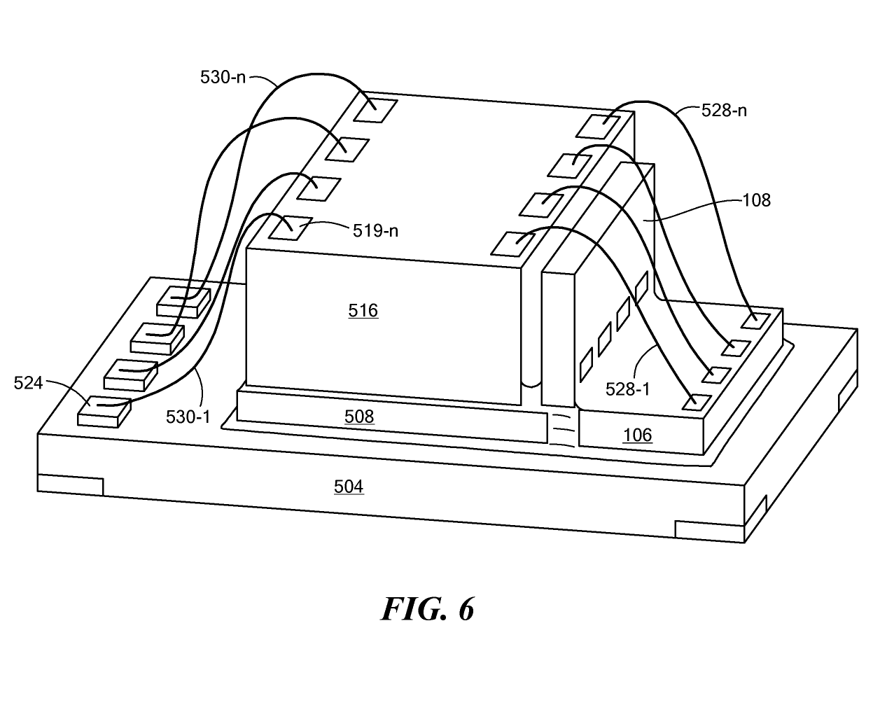

Bond wires 528-n are used to attach the connection pads 306-n to the base device contact pads 518-n. Another set of bond wires 530-n are used to couple the contact pads 519-n of the base device 516 to the PCB contacts 524 of the PCB 504. The entire device, as shown in FIG. 6, comprising the PCB 504, the base device 516 and the magnetic field sensor 104 is then encapsulated and/or molded to provide a single device for subsequent integration into, for example, a cell phone.

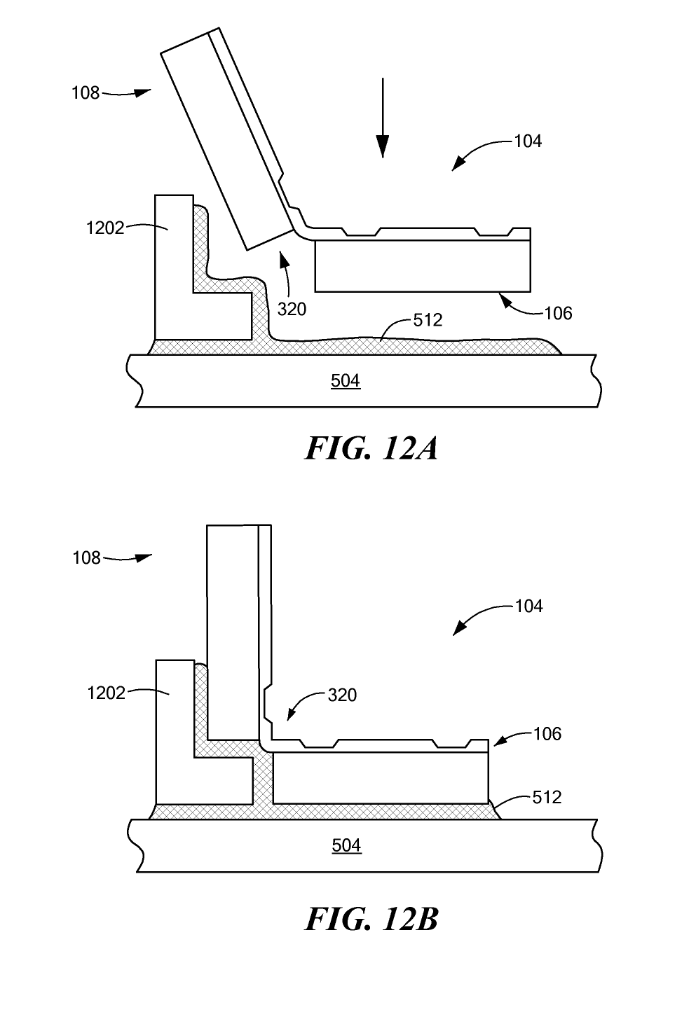

Alternatively, the orthogonality of the first portion 106 to the second portion 108 may be established without the use of an ASIC device as is shown in FIGS. 12A and 12B, for example. Here, the PCB 504 has a guide spacer 1202 attached, for example, by die attach processing 512, to an upper surface of the PCB 512. The device 104 is then picked and placed onto the PCB 512 such that the second portion 108 comes into contact with the guide spacer 1202 as the device 104 is being brought toward the PCB 504. This contact with the guide spacer 1202 deflects the second portion 108 to be at a right angle to the first portion 106 due to the height of the guide spacer 1202 and its location with respect to the first portion 106. The relationship between the first portion 106 and the second portion 108 is maintained with the die attach processing 512, for example, epoxy, and may also include potting material after all connections are made and testing is complete. Further, similar to the embodiment described above, bond wires (not shown) may be attached as necessary.

One of ordinary skill in the art will understand that the guide spacer 1202 may be configured to establish any desired angle between the first and second portions and not just 90°.

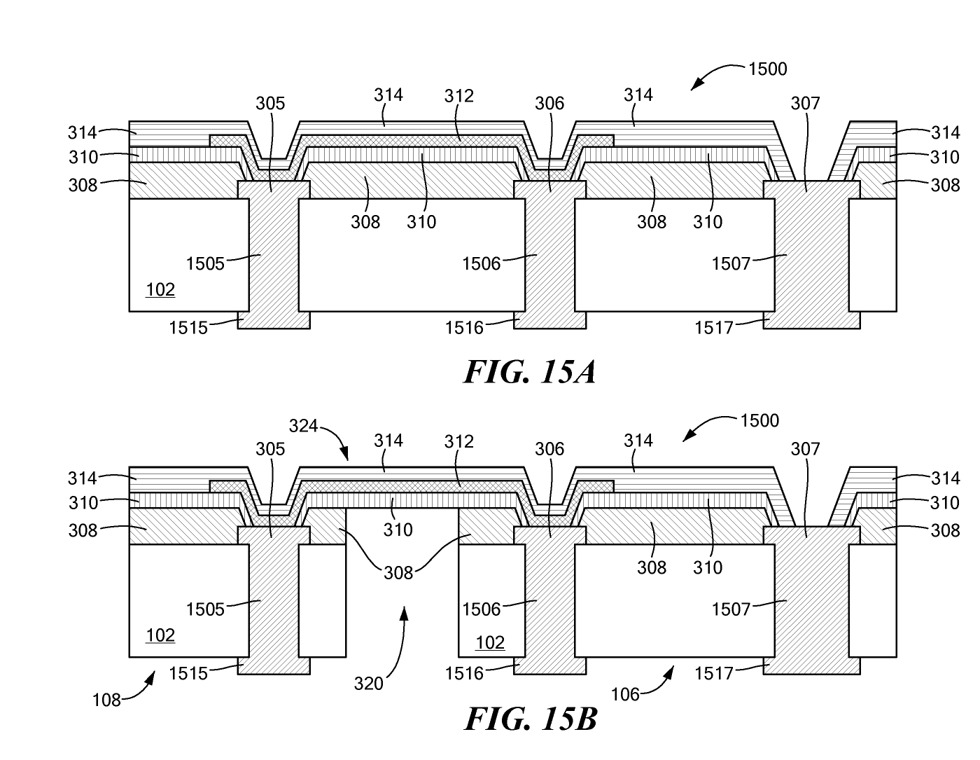

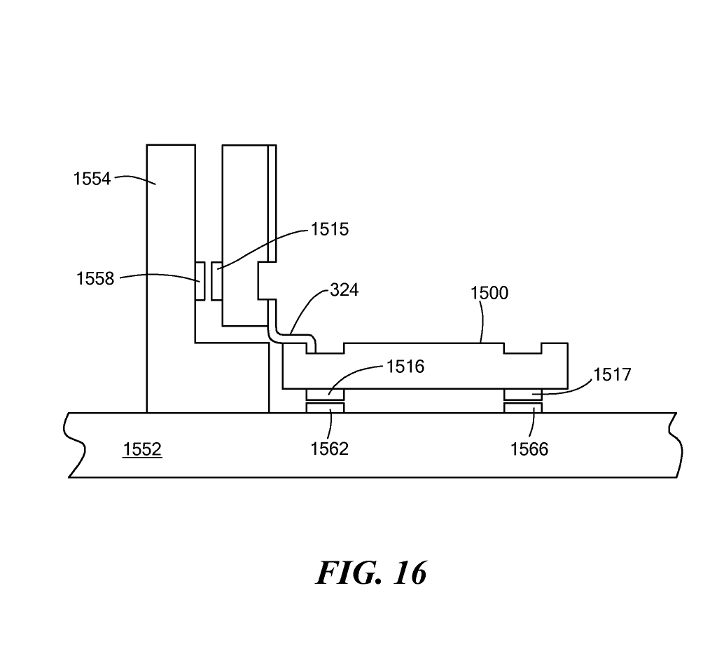

A modification of the embodiment shown in FIGS. 3D and 3E will now be described with respect to FIGS. 15A, 15B and 16. Specifically, a device 1500 is generally similar to the device 300 except that each of the first, second and third connection pads 305-307 is coupled to first, second and third vias 1505-1507, respectively. Each of the first, second and third vias 1505-1507 terminates with a first, second and third via pad 1515-1517, respectively. The first, second and third vias 1505-1507 may be referred to as “through silicon vias.” As shown in FIG. 15B, the gap 320 is created and the vias allow for access to circuitry on the first and second portions as may be necessary. One of ordinary skill in the art will understand that not all of the connection pads may have a corresponding via and, therefore, not all will necessarily be accessed.

Referring to FIG. 16, the device 1500 may be oriented on a substrate 1552 by, for example, a PCB with a guide 1554 positioned thereon. The guide 1554 may have a guide pad 1558 positioned thereon. An upper surface of the substrate 1552 may have first and second guide pads 1562, 1566 provided thereon. The device 1500, when placed downward toward the substrate 1552 and in proximity to the guide 1554, will allow for the first and second portions to be oriented at the desired angle with respect to one another. The first, second and third via pads 1515-1517 are configured to oppose the guide pad 1558 and first and second substrate contact pads 1562, 1566 and may be connected by any one of a number of methods as known, including, but not limited to, wave soldering, ball grid array, etc. Thus, an electrical contact from the circuits on the device to either the substrate 1552 or the guide 1554 may be made possible.

In addition, one of ordinary skill in the art will understand that either an anisotropic conductive film (ACF) or an anisotropic conductive paste (ACP) may be placed between the guide 1554 and the device 1500, along with bump processing where necessary, in order to create an electrical connection between them.

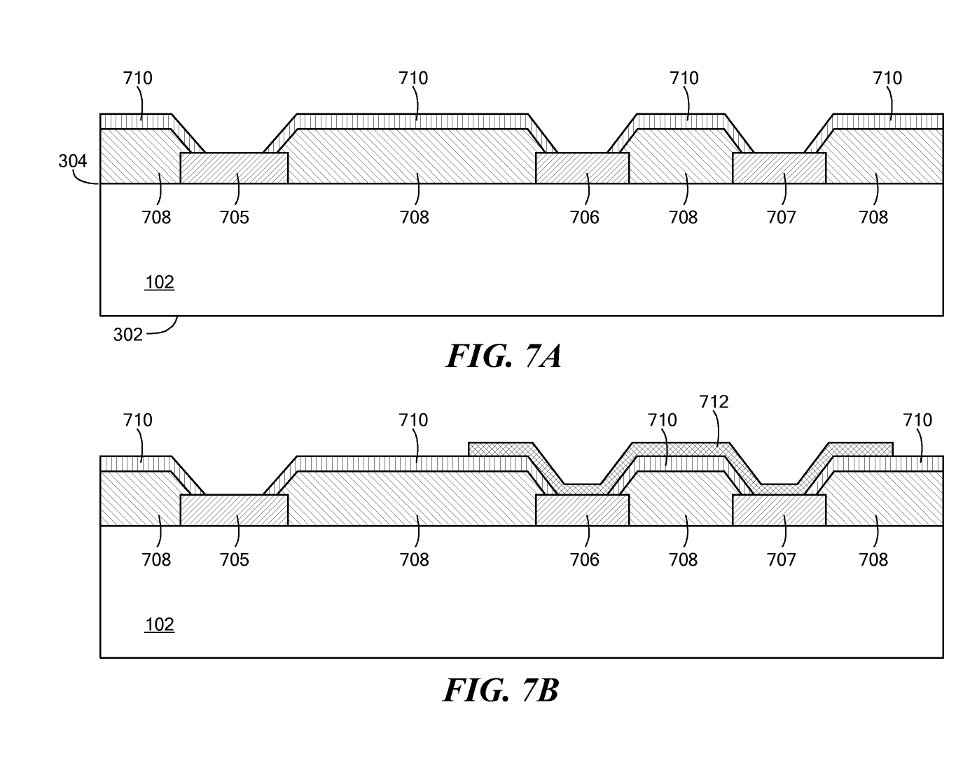

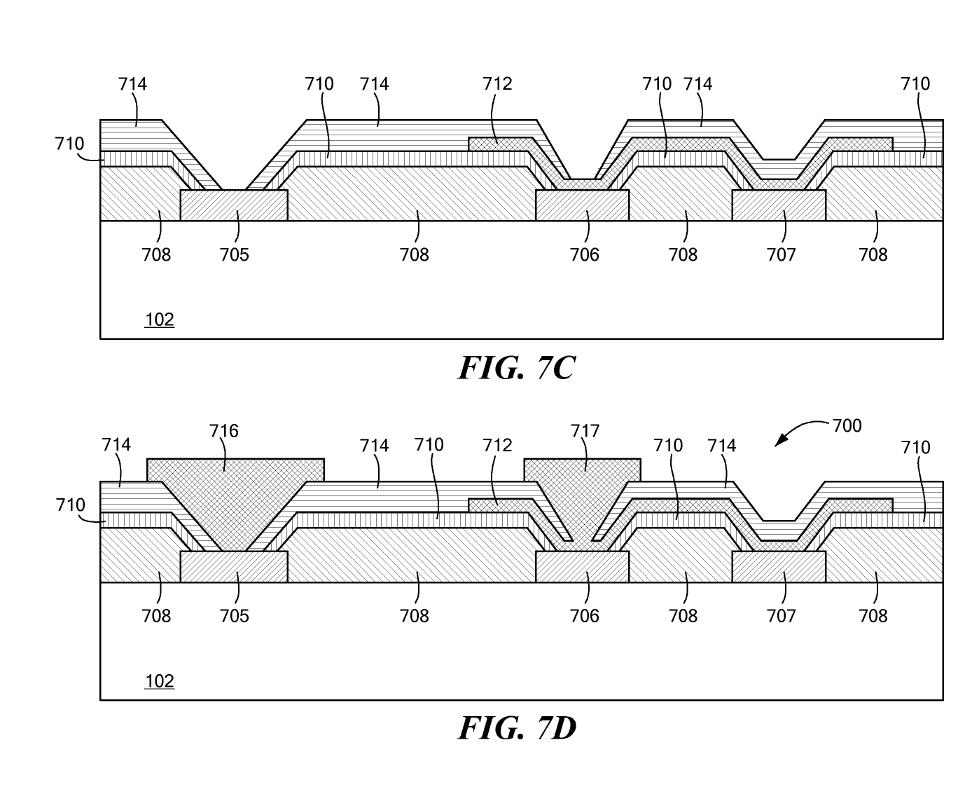

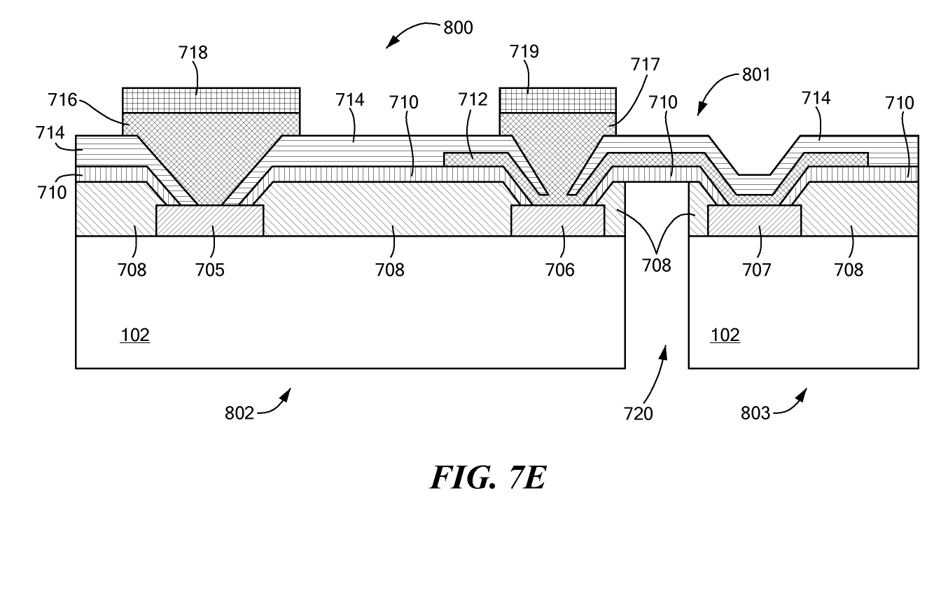

A second embodiment of the present invention, similar to the first embodiment described above, also begins with a wafer 102 having an upper surface 304 and a back surface 302, as shown in FIG. 7A. First, second and third connection pads 705, 706 and 707 are disposed by any one of a number of known technologies on the upper surface 304. Subsequently, a passivation layer 708 is disposed on the upper surface 304, however, leaving the connection pads 705, 706 and 707 exposed. Similarly, a lower insulating layer 710 is disposed over the passivation layer 708 but also leaving the connection pads 705, 706 and 707 exposed.

A coupling strip 712 is disposed over a portion of the lower insulating layer 710 so as to electrically couple the second connection pad 706 to the third connection pad 707, as shown in FIG. 7B.

An upper insulating layer 714 is provided over the lower insulating layer 710 and the coupling strip 712. The upper insulating layer 714, however, is masked so as to leave exposed the first connection pad 705 as well as the portion of the coupling strip 712 that is coupled to the second connection pad 706, as shown in FIG. 7C.

A first conductive bump 716 is disposed in the opening in the upper insulating layer 714 corresponding to the first connection pad 705 as shown in FIG. 7D. A second conductive bump 717 is provided in the upper insulating layer 714 to couple with the exposed portion of the coupling strip 712 corresponding to the second connection pad 706.

A first solderable portion 718 is coupled to the first conductive bump 716 and a second solderable portion 719 is coupled to the second conductive bump 717, as shown in FIG. 7E. Similar to the description above with respect to removing a device from the wafer 102, a gap 720 is cut through the wafer 102, in one example, accessed through the back surface 302, through the wafer body 102 and the passivation layer 708, as shown in FIG. 7E. Thus, the insulating layer 710, the coupling strip 712 and the upper insulating layer 714 create a foldable bridge portion 801 between a first portion 802 and a second portion 803.

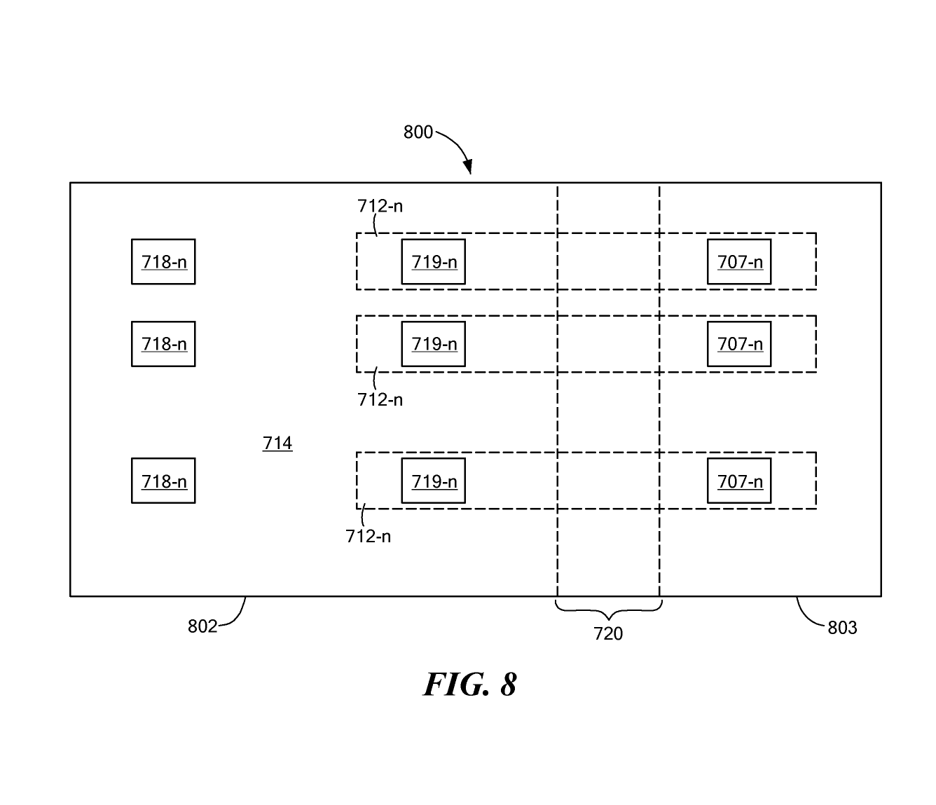

As the device 700 is bendable by operation of the foldable bridge portion 801, those layers or strips in the foldable bridge portion 801 are of a thickness and/or material that facilitates being bendable without breaking. Such materials include, but are not limited to, metals, semiconductors, insulators, etc. One of ordinary skill in the art will understand that various materials, conductive and non-conductive, can be used in the foldable bridge portion 801 to provide the functionality described herein. As shown in FIG. 8, a top view of the device, one can see that the first solderable portion 718-n and the second solderable portion 719-n are accessible, i.e., extend, from the upper insulating layer 714. The second solderable portion 719-n is electrically coupled to the corresponding third connection pad 707-n. Thus, one of ordinary skill in the art will understand that the plurality of coupling strips 712-n are at a same level with one another.

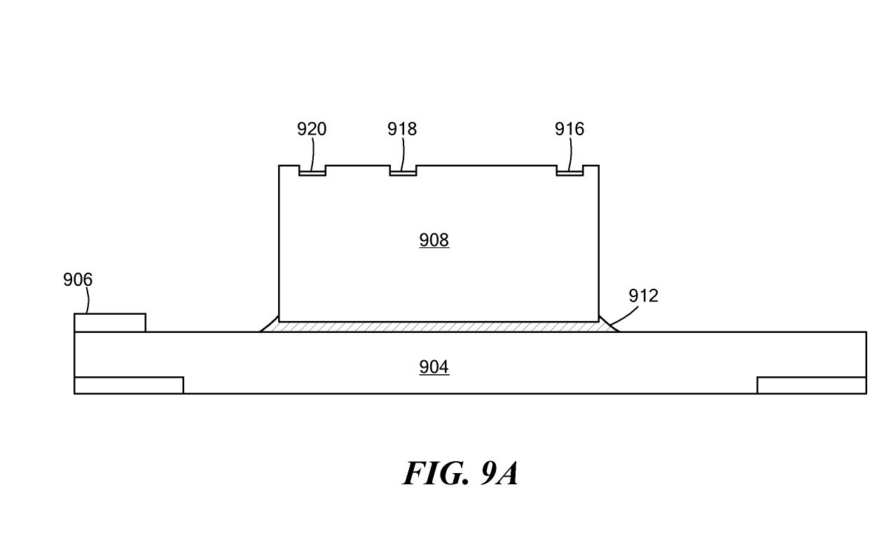

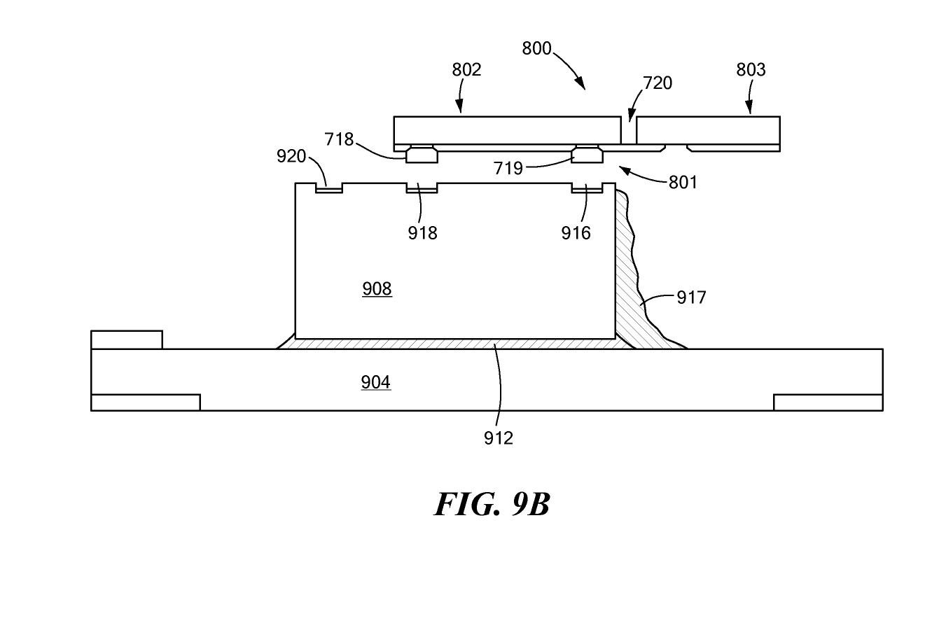

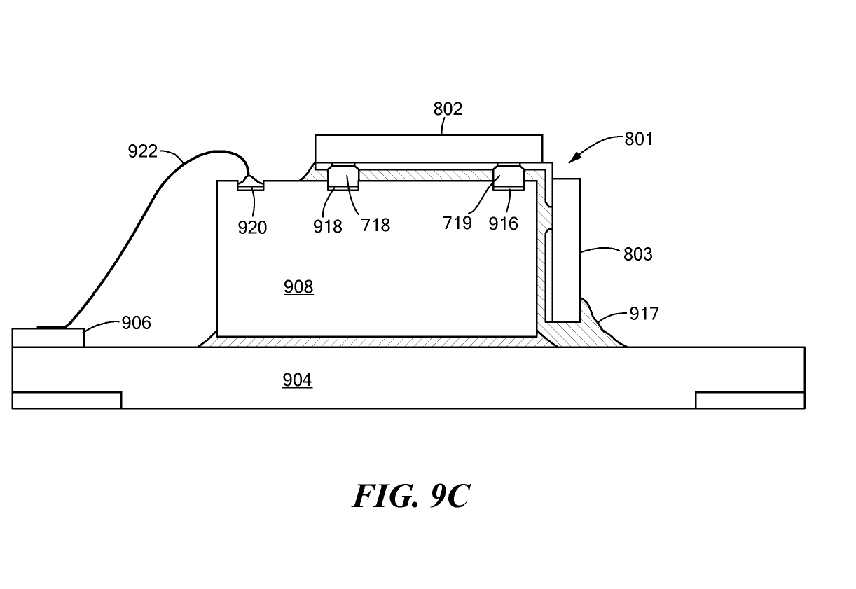

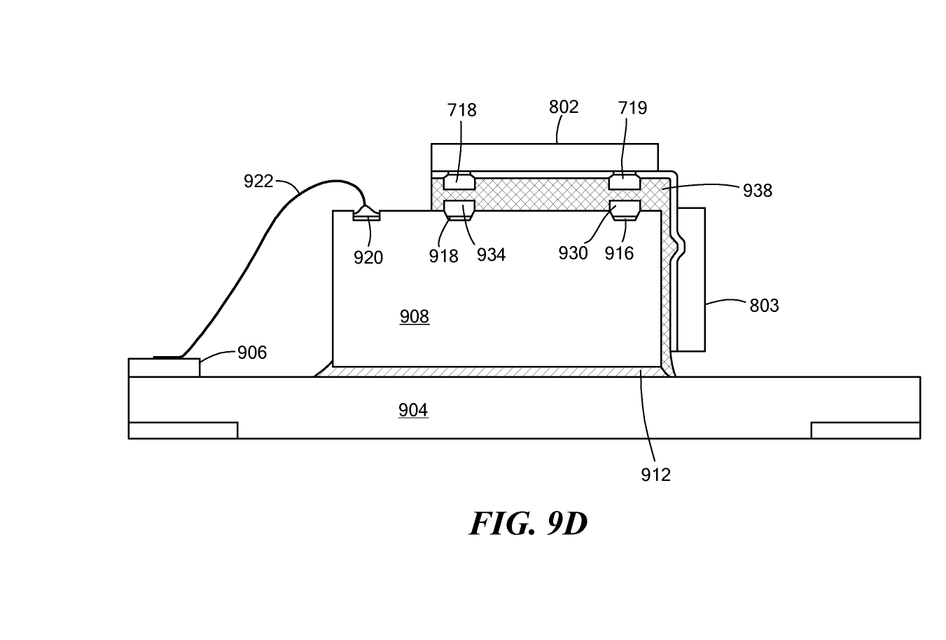

The magnetic field sensor 800 now must be integrated with a base device, similar to the first embodiment described above. Thus, referring to FIG. 9A, a PCB 904 is provided with a base device 908 attached 912 to a top surface of the PCB 904. As above, the attachment 912 of the base device 908 to the PCB 904 may be accomplished by any one of a number of known attachment technologies. A top surface of the base device 908 includes first, second and third base device contact pads 916, 918 and 920, respectively. The PCB 904 also includes at least one PCB contact pad 906.

In the attachment process, the magnetic field sensor 800 is inverted and oriented such that the solderable portion 719 is aligned with the base device contact pad 916 and the solderable portion 718 is aligned with the second base device contact pad 918, as shown in FIG. 9B. Once the sensor 800 is so aligned, the second portion 803 is then bent about the foldable bridge portion 801 so as to be oriented orthogonally with respect to the first portion 801. The device 800 is then maintained in that orientation by the application of, for example, epoxy 917. A bond wire 922 is then provided to attach the third base device contact pad 920 to the PCB contact pad 906, as shown in FIG. 9C.

Alternatively, as shown in FIG. 9D, a first bump 930 may be placed on the first base device contact pad 916 and a second bump 934 may be placed on the second base device contact pad 918 by any of the known bump processing technologies. Either an anisotropic conductive film (ACF) or an anisotropic conductive paste (ACP) 938 may be placed between the base device 908 and the sensor 800. One of ordinary skill in the art will understand how either ACF or ACP is provided and placed in order to accomplish the connection between the sensor 800 and the base device 908.

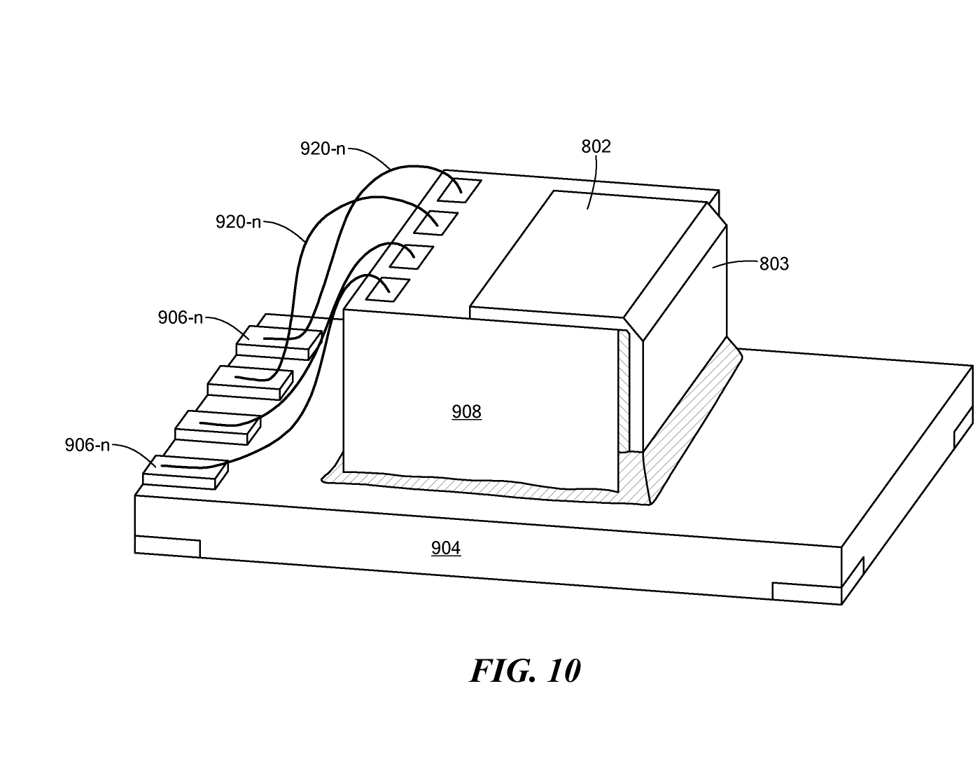

As shown in the perspective view of the device in FIG. 10, a plurality of bond wires 920-n are provided to couple a plurality of signals from the base device 908 to the PCB 904. Similar to the first embodiment, the assembly of the PCB 904, the base device 908 and the attached sensor 800 is then covered with epoxy or other packaging technology in order to provide a single unitary device for subsequent insertion into a device, for example, a phone having GPS capabilities.

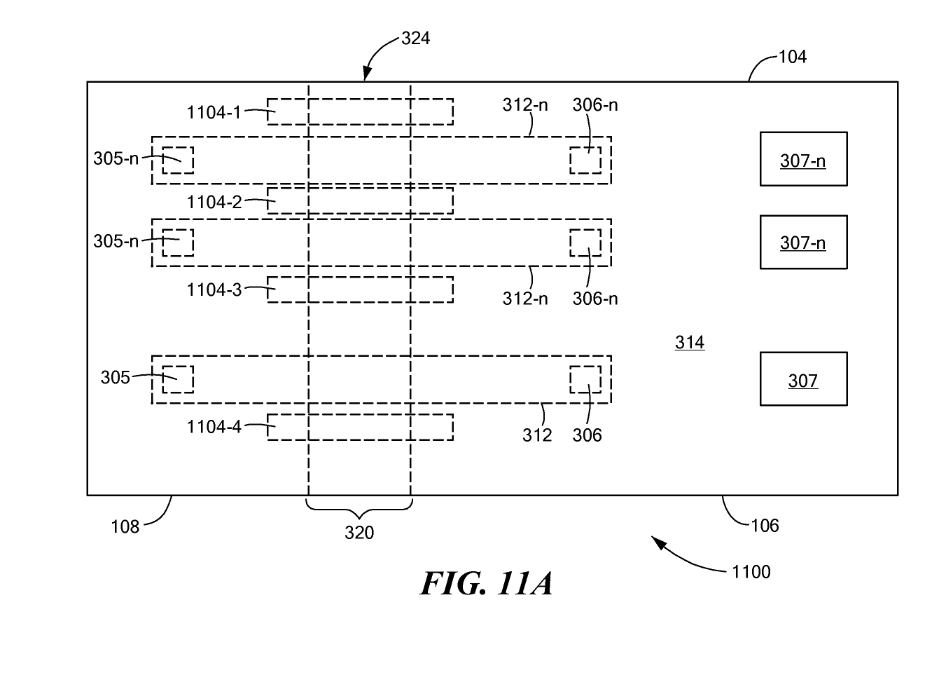

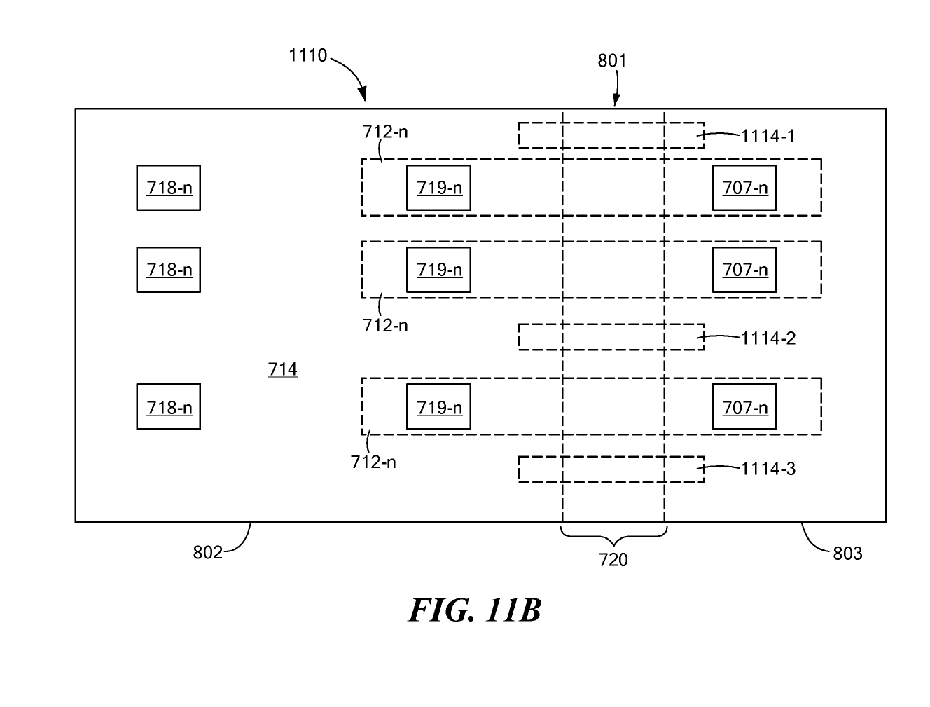

In another embodiment of the present invention, one or more metal strips are provided in order to strengthen the foldable portion. Referring now to FIG. 11A, a device 1100, which is similar to the device shown in FIG. 4, includes a plurality of metal strips 1104-n extending from the first portion 106 to the second portion 108. These metal strips 1104-n are provided at the same level as the coupling strips 312-n although the metal strips 1104-n do not couple a circuit on the first portion 106 to a circuit on the second portion 108. The metal strips 1104-n provide additional strength across the foldable bridge portion 324.

Referring now to FIG. 11B, a device 1110, which is similar to the device shown in FIG. 8, includes a plurality of metal strips 1114-n extending from the first portion 106 to the second portion 108. These metal strips 1114-n are provided at the same level as the coupling strips 712-n although the metal strips 1114-n do not couple a circuit on the first portion 802 to a circuit on the second portion 803. The metal strips 1114-n provide additional strength across the foldable bridge portion 801.

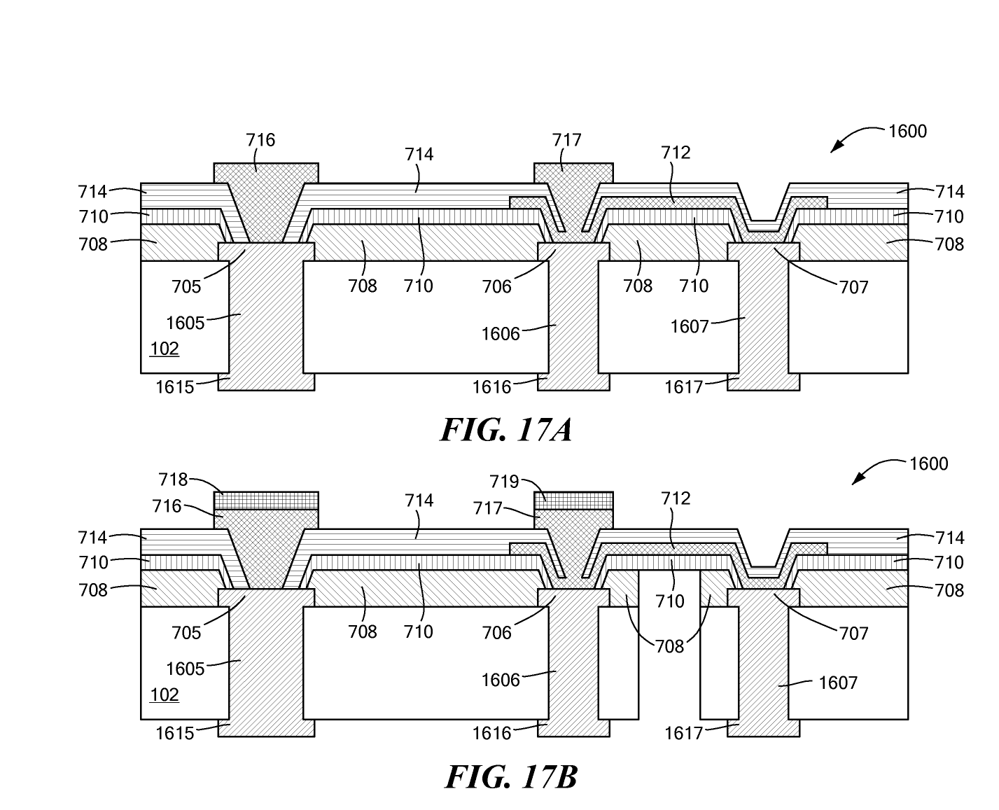

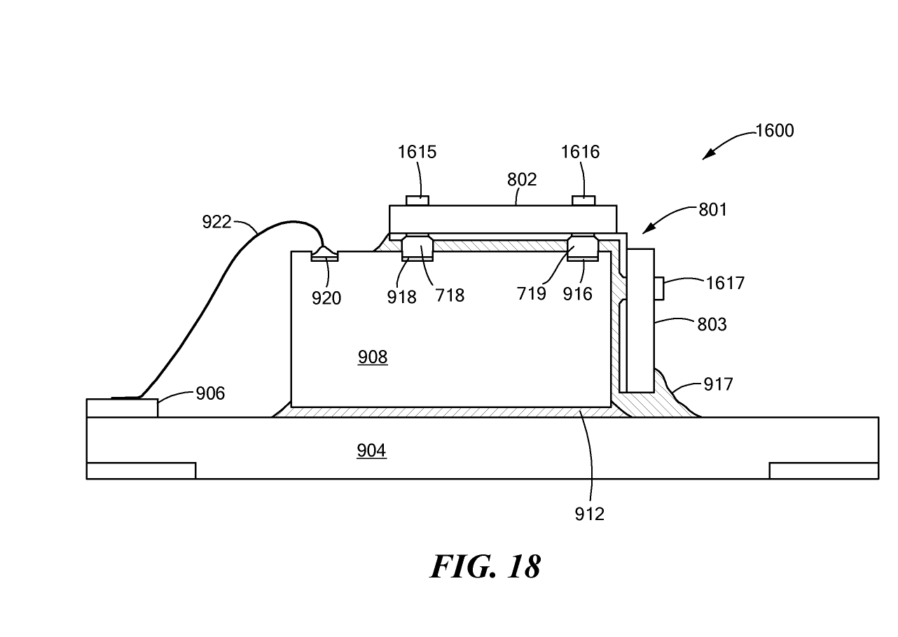

A modification of the embodiment shown in FIGS. 7D and 7E will now be described with respect to FIGS. 17A, 17B and 18. Specifically, a device 1600 is generally similar to the device 700 except that each of the first, second and third connection pads 705-707 is coupled to first, second and third vias 1605-1607, respectively. Each of the first, second and third vias 1605-1607 terminates with a first, second and third via contact pad 1615-1617, respectively. The first, second and third vias 1605-1607 may be referred to as “through silicon vias.” As shown in FIG. 17B, the gap 720 is created and the vias allow for access to circuitry on the first and second portions as may be necessary. One of ordinary skill in the art will understand that not all of the connection pads may have a corresponding via and, therefore, not all will necessarily be accessed.

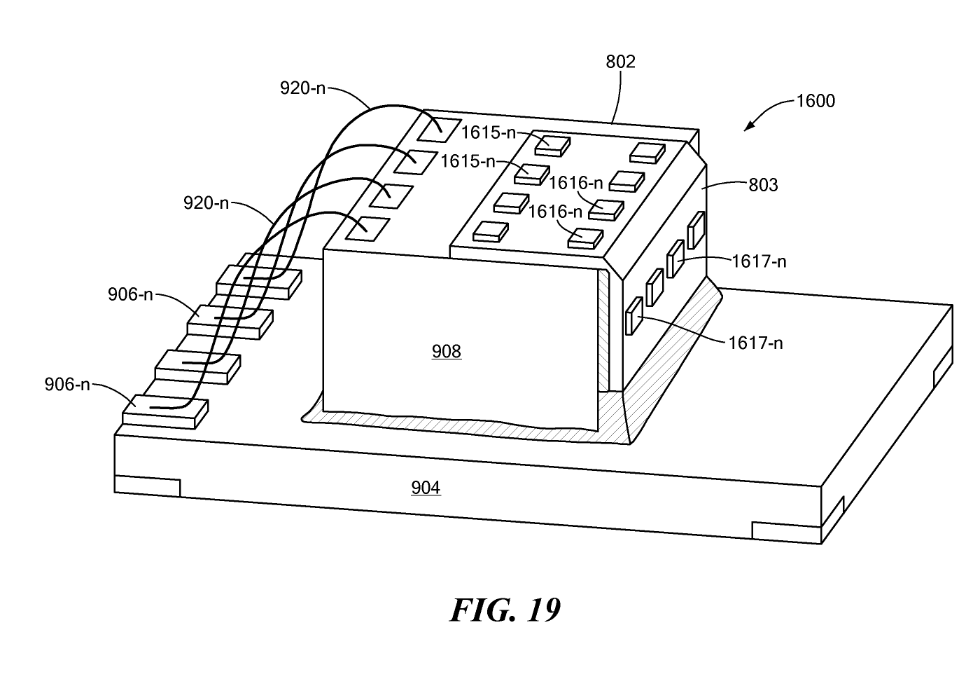

Referring to FIG. 18, the device 1600 may be oriented on the base device 908, similar to that which has been described above. Advantageously, the first, second and third contact pads 1615-1617 are then “externally” available for connection. As shown in FIG. 19, the first, second and third via contact pads 1615-1617 may present multiple locations for connecting by, for example, bond wire soldering.

In addition, one of ordinary skill in the art will understand that either an anisotropic conductive film (ACF) or an anisotropic conductive paste (ACP) may be placed between the base device 908 and the device 1600, along with bump processing where necessary, in order to create an electrical connection between them.

In another embodiment of the present invention, rather than defining the device to have two portions with one gap between, three portions, with two gaps, are defined. Advantageously, in the case of a three-dimensional (3D) sensor application, the device can be bent to have two angled portions.

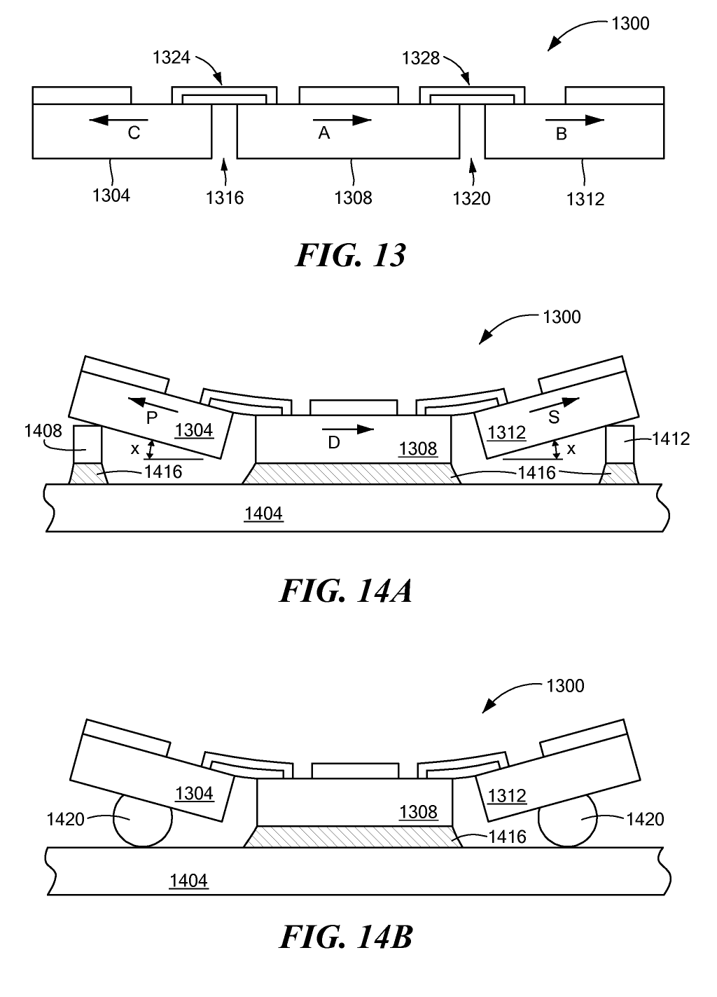

Referring now to FIG. 13, a device 1300 includes first, second and third portions 1304, 1308 and 1312 with a first gap 1316 between the first and second portions 1304, 1308 and a second gap 1320 between the second and third portions 1308, 1312. A first foldable bridge portion 1324 extends across the first gap 1316 and a second foldable bridge portion 1328 extends across the second gap 1320. The foldable bridge portions and gaps were created in a same manner as has been described above with the deposition of layers and strips and the removal of substrate material.

The device 1300 may include a sensor structure fabricated on its surface. Thus, in the case of a 3D sensor application, each portion 1304, 1308 and 1312 may have a respective sensor structure P, D, S fabricated on the surface. In one example, as will be discussed below, the sensors D, S on the second and third portions 1308, 1312, respectively, are oriented in a first direction, represented by arrows D, S and the sensor P on the first section 1304 is oriented in a second direction represented by arrow P.

Referring now to FIG. 14A, in order to obtain out of plane sensing from the device 1300, a substrate 1404, for example, a printed circuit board (PCB) is provided with first and second spacers 1408, 1412 attached, for example, by epoxy 1416 or any other known mechanism, to an upper surface of the substrate 1404. The device 1300 is then placed on the substrate 1404 such that each of the first and third portions 1304, 1312 is out of plane, with respect to the second portion 1308, at a same angle X.

Alternatively, referring to FIG. 14B, rather than building the PCB 1404 to accomplish the out-of-plane configuration, bumps 1420, 1422 could be placed on the bottom of the first and third portions 1304, 1312, respectively. The bumps 1420, 1422 would be sized to maintain the two portions 1304, 1312 at the desired angles.

Thus, when the first portion 1304 and the third portion 1312 are at the same tilt angle X, the respective sensors P, S would have the same out of plane sensing component. As a result, if an output of the first sensor P is S_{P} and an output of the third sensor S is S_{S}, then the sum S_{P}+S_{S} is an out of plane sensing signal S_{OP}, and the difference S_{P}−S_{S} is an in plane sensing signal S_{IP}.

The second portion 1308 may operate as an interconnection and landing space for bond wires in order to interface with other devices in the system such as, for example, an ASIC device. Further, the sensor on the second portion 1308 may be optional but could operate as an additional in-plane sensor.

A pick and place machine may be used to place the device 1300 on to the substrate 1404. As the pick and place machine pushes down the device 1300, the first and third portions 1304, 1312, will be deflected upwards by those spacers 1408, 1412 to form the defined angle X. This angle X can be anywhere between 0 and 90 degrees. In one embodiment, an optimum value can be chosen, for example, 30 degrees.

Alternatively, the device 1300 may be placed on top of a device such as an ASIC and then the ASIC attached to another substrate, for example, a PCB, as part of a final package. Bond wires can be attached as necessary for electrical interconnection or other purposes.

In a variation of the device 1300, either of the first or third portions 1304, 1312, can be eliminated to reduce size and cost. In such a case, the out of plane sensing signal S_{OP}, described above, is no longer valid. An out of plane function may then be determined by comparing the output of the in-plane sensor S_{D} and the remaining out of plane sensor, either S_{P} or S_{S}. While it is possible that a residue error of S_{OP} could produce a heading error in a compass, such an error may be reduced by application of an appropriate correction algorithm.

In another embodiment of the present invention, a multi-plane device is made from a single plane substrate, for example, a wafer, by incorporating a flexible component.

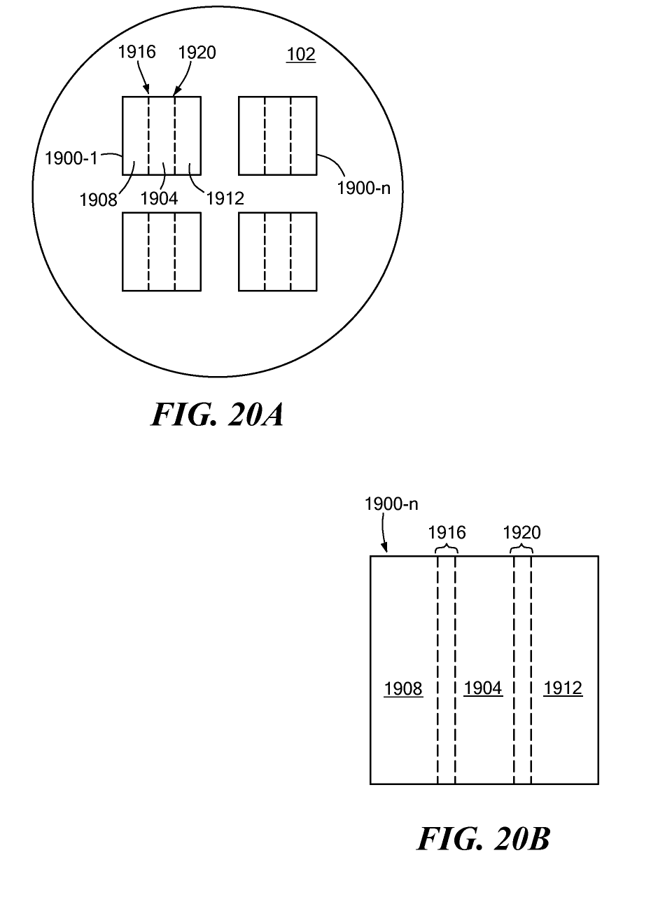

Generally, as is known to one of ordinary skill in the art, a wafer 102, as shown in FIG. 20A, is used as the basis on which a plurality of devices 1900-n are provided. Usually, the wafer 102 is made from a semiconductor material, e.g., silicon, although the embodiments of the present invention are not limited thereto and other base materials may be used as is well known to those of ordinary skill in the art. As will be discussed in more detail below, in this embodiment of the present invention, each device 1900-n includes a first portion 1904, a second portion 1908 and a third portion 1912 with a first clear zone 1916 between the first and second portions 1904, 1908 and a second clear zone 1920 between the first and third portions 1904, 1912.

Referring now to FIG. 20B, the first, second and third portions 1904, 1908, 1912 may contain any type of circuitry or components as may be desired and positioned, or built up, by any of many known methods. It is necessary, however, that there be no circuitry or functional devices placed in any of the clear zones 1916, 1920.

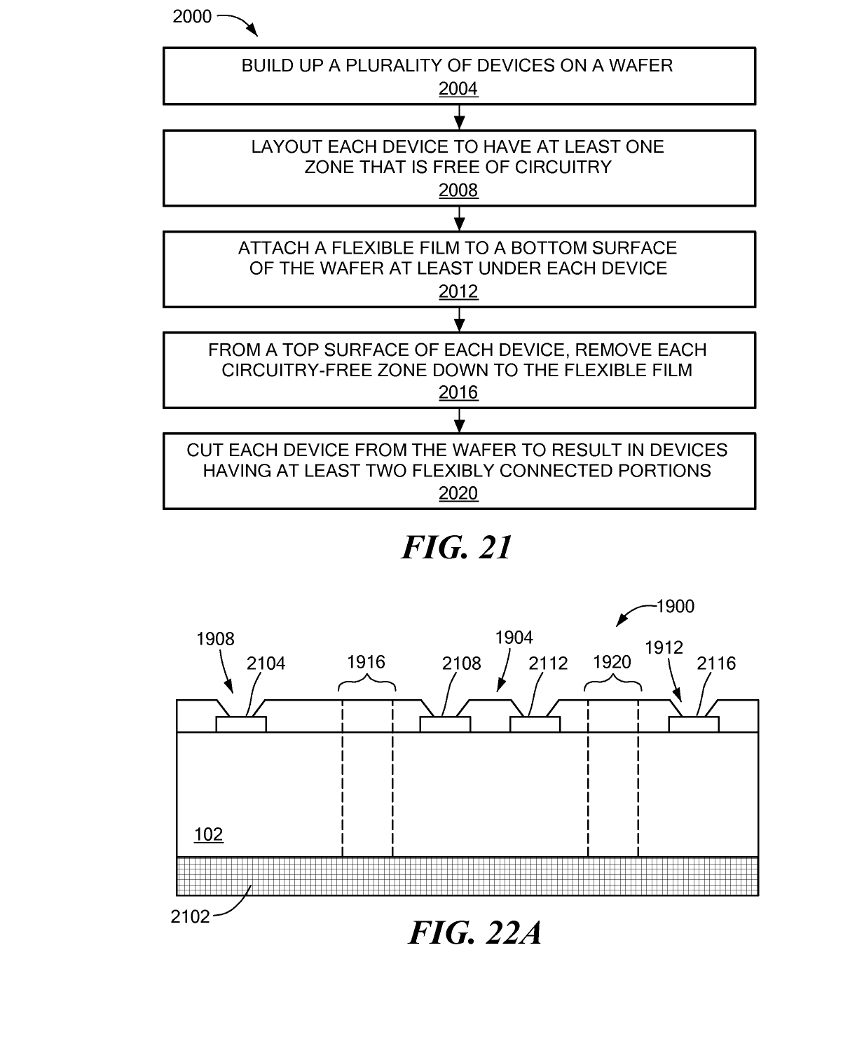

As an overview of a method of manufacturing, a method 2000, as shown in FIG. 21 starts at step 2004 where a plurality of devices 1900 are built up on the wafer 102. As known to those of ordinary skill in the art, depending upon the size of the wafer 102 a plurality of such devices 1900 may be provided. Well known processes such as, for example, lithography and thin film material deposition may be used to manufacture these devices. In addition, step 2008, each device is arranged to have at least one clear zone that separates at least two portions of the device 1900 from each other.

Next, step 2012, a flexible film is attached to a bottom surface of the wafer at least under each device 1900. Alternatively, adhesive tape or plated metal could be used in place of the flexible film. Subsequently, step 2016, from a top surface of each device, each clear zone in the wafer is removed down to the flexible film. Once the free zones have been cut away, each individual device is cut from the wafer, step 2020, for subsequent additional processing as necessary.

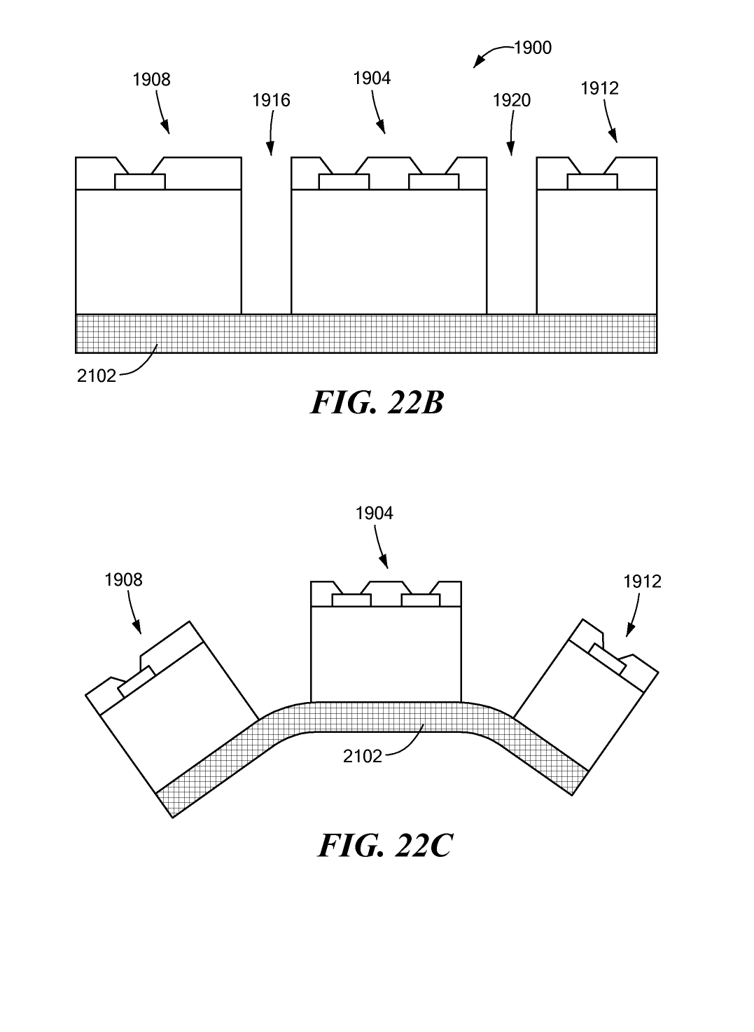

Referring now to FIG. 22A, a cross-section of the device 1900, the substrate 102 includes a flexible piece of material, for example, a film 2102 attached to a bottom surface. Merely for explanatory purposes, the first portion 1904 is shown as having two connection pads 2108, 2112 that have been left exposed in an upper surface. These connection pads may have been formed in a manner similar to that which has been described above. Of course, one of ordinary skill in the art will understand that there may be multiple connection pads and/or pads that are not exposed but instead covered. The second portion 1908 includes a connection pad 2104 and the third portion includes a connection pad 2116. Each of the first and second clear zones 1916, 1920 is free from any components from either of the adjacent portions.

As described above with reference to step 2016 in method 2000, the material in each of the free zones 1916, 1920 is removed down to the flexible film portion 2102. The material of any upper deposited layer on the substrate 102 can be removed by blade sawing, laser sawing, an etching operation with appropriate masking or by any combination of the foregoing. The device 1900, as shown in FIG. 22B, is the result of the removal of the free zones 1916, 1920. It should be noted that it is not necessary that all of the wafer material be removed as some may be left that does not interfere with the flexibility of the film portion 2102.

Advantageously, the flexible portion 2102 allows the first, second and third portions 9104, 1908, 1912 to be oriented in an out-of-plane manner as shown in FIG. 22C. Thus an out-of-plane carrier has been created from an in-plane manufacturing process.

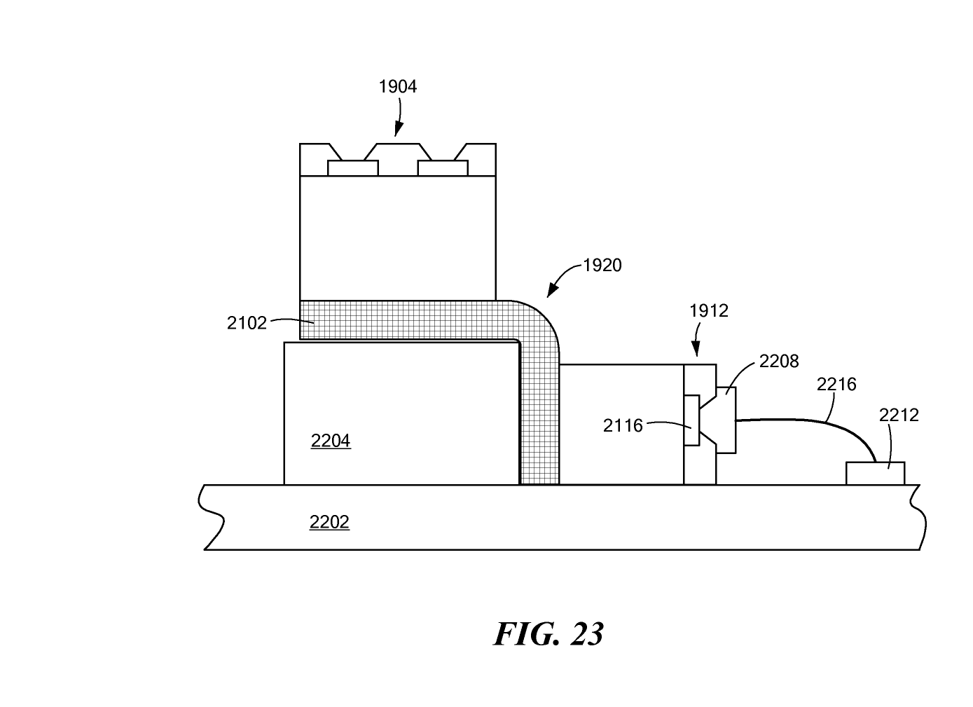

As a result, an out-of-plane arrangement of the device 1900 is made possible as shown in FIG. 23. Here, a substrate 2202, for example a PCB, includes a guide or support 2204 mounted on an upper surface thereof. The device 1900 is then placed, in a manner similar to that described above, on the support 2204 such that the first portion 1904 and the third portion 1912 are at a predetermined angle to one another. The device 1900 may be attached by, for example, epoxy, or any other known mechanism. It should be noted that there is no second portion in this example device 1900 although there could be, however, only two portions are shown for simplicity of explanation. The substrate 2202 may include a substrate contact pad 2212 for connection to the connection pad 2116 of the third portion 1912. Optionally, the substrate contact pad 2116 may include a bump 2208 provided by a bump process for connecting to the substrate contact pad 2212 by a bond wire 2216. One of ordinary skill in the art will understand that there are many known ways for providing such connections.

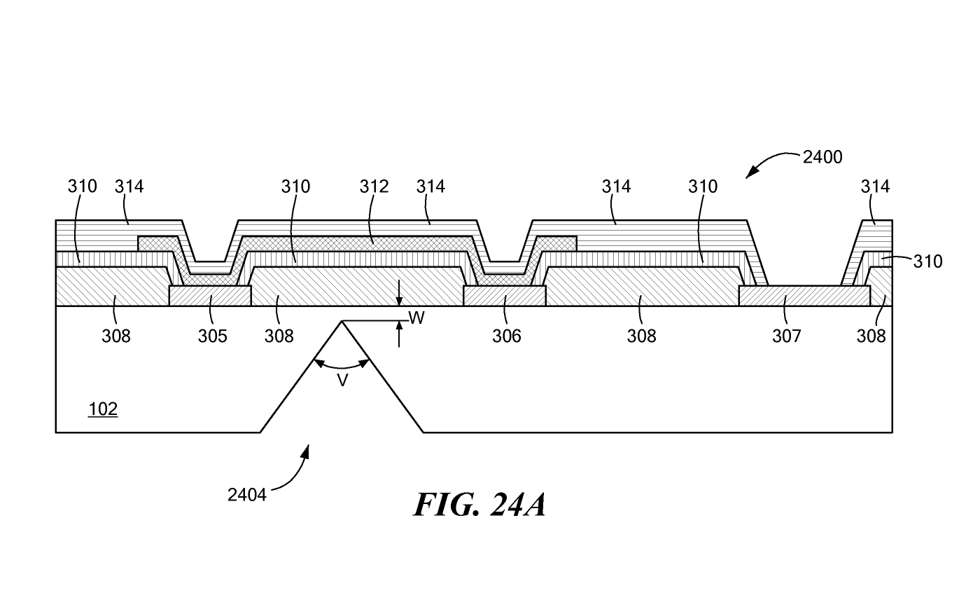

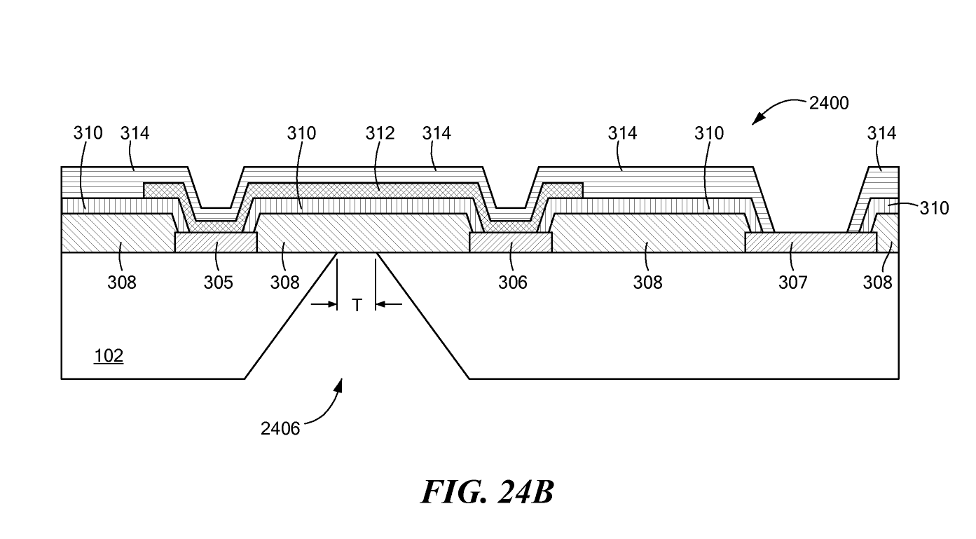

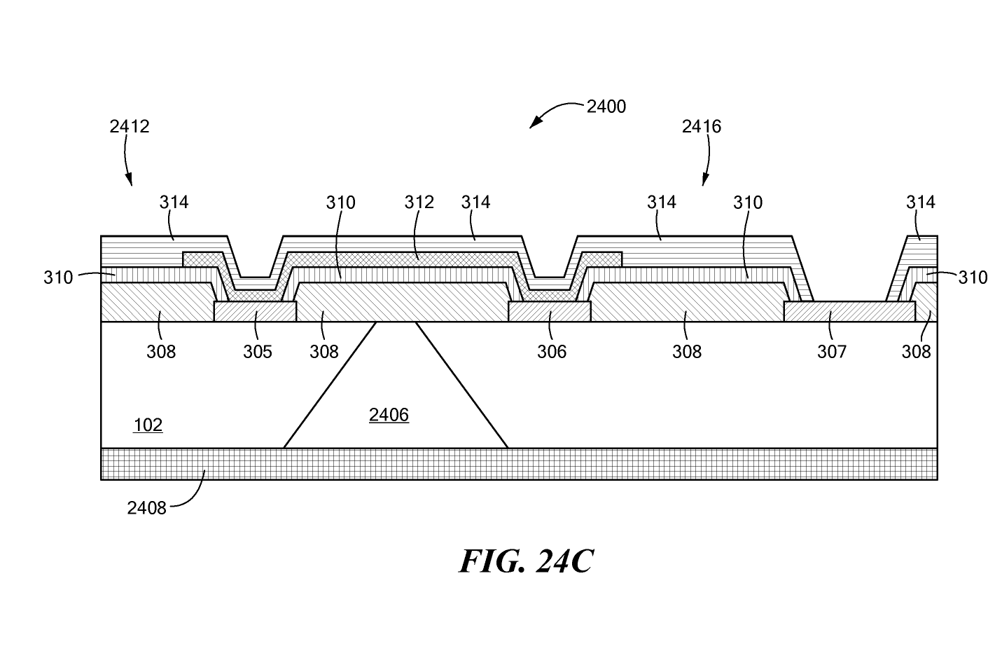

Referring now to FIG. 24A, an embodiment of the present invention includes a device 2400, similar in construction to the device 300 shown in FIG. 3D, that includes an alternate version of the gap. Here, a gap is provided with angled walls rather than straight walls as shown in the foregoing embodiments thereby allowing for various positioning of one portion with respect to another portion. To create the device 2400, initially, a first wedge gap 2404 is created in the substrate material 102, by, for example, a V-shaped blade cut. Of course, one of ordinary skill in the art will understand that other methods or tools could be used to create the first wedge gap. The blade cut, however, is adjusted in order not to damage the passivation layer 308 underneath the lower insulating layer 310 and the coupling strip 312 along with the upper insulating layer 314 that create the foldable portion. Accordingly, the blade is set to remove material no closer than a distance W from the lower passivation layer 308. The first wedge gap 2404 may have an initial angle V that may be chosen depending upon the material, the sharpness of the blade and any other design considerations.

Subsequently, as shown in FIG. 24B, the first wedge gap 2404 is modified to create an expanded wedge gap 2406. The expanded wedge gap 2406 may be created by, for example, etching the substrate material 102 by any one of many known lithography processes and the like. Of course, one of ordinary skill in the art will understand that other methods or tools could be used to create the expanded wedge gap. As a result, the expanded wedge gap 2406 has a “flat” portion having a width T, as shown.

A layer of die attach film 2408 is placed across the bottom of the substrate 102 and thus covers the expanded wedge gap 2406, as shown in FIG. 24C. The die attach film 2408 is flexible and does include some amount of stickiness and such die attach film may be available from, for example, Hitachi Chemical Company.

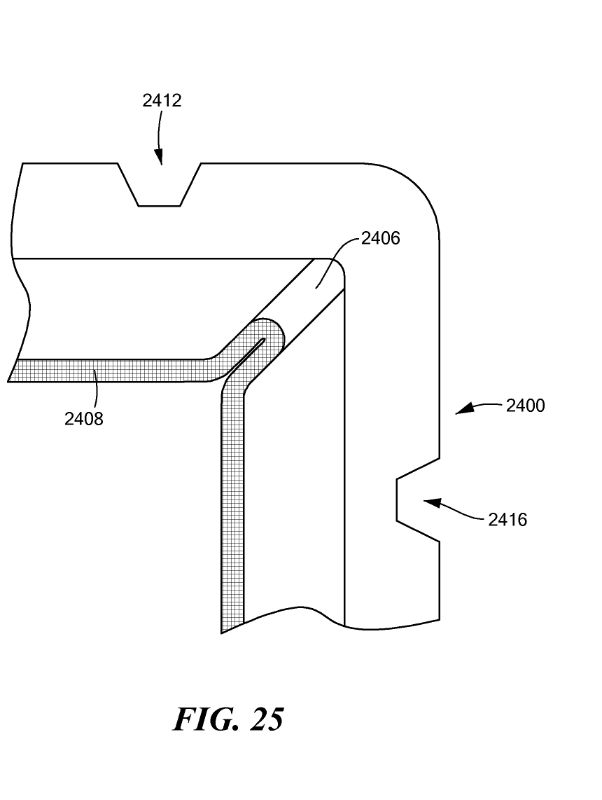

The provision of the expanded wedge gap 2406 and the die attach film 2408 allows for first and second portions 2412, 2416 to be arranged at a predetermined angle with respect to one another. Thus, the first portion 2412 can be moved with respect to the second portion 1416 by operation of the foldable portion, as described above, resulting in the configuration shown in FIG. 25. As shown, the expanded wedge gap 2406 is reduced by the moving of the first portion 2412 with respect to the second portion 2416. The die attach film 2408, being a flexible film, will tend to roll up into the wedge gap 2406. The width T is generally about twice the thickness of the film 1408.

Due to the stickiness of the die attach film 2408, the device 2400 will be maintained in the orientation that will facilitate installation of the device 2400 in a subsequent assembly.

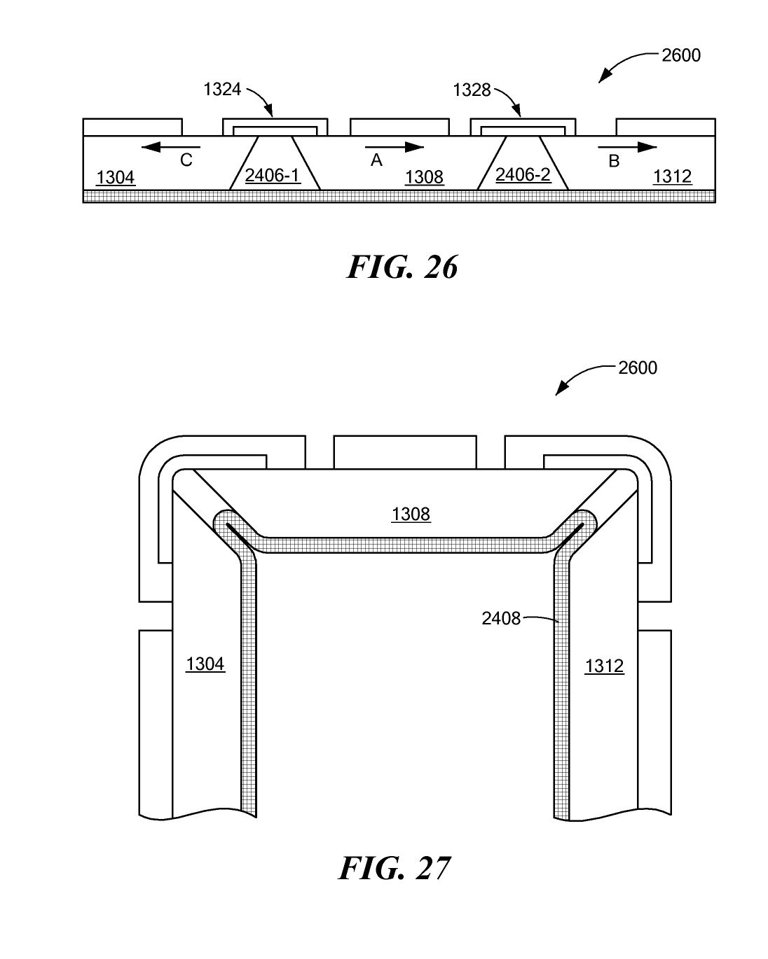

Referring now to FIG. 26, in another embodiment of the present invention, a device 2600 can be provided with multiple expanded wedge gaps 2406-1, 2406-2 as a modification of the device 1300 shown in FIG. 13. The die attach film 2408 allows for the device 2600 to be bent into a “U” shape as shown in FIG. 27.

It should be noted that the packaging described herein can be applied to magnetic sensors, for example, an electronic compass. Further, the packaging may be applied to accelerometer sensors, gyroscope sensors and electrical field sensors in addition to any circuitry amenable to placement on a wafer or similar planar substrate.

Still further, a device may have multiple foldable portions, for example, one on a top surface and another on the bottom surface to provide different configurations of the substrate.

Having thus described several features of at least one embodiment of the present invention, it is to be appreciated that various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A foldable substrate comprising:
a first substrate portion comprising a first upper surface;
a second substrate portion comprising a second upper surface; and
a foldable bridge portion coupling the first substrate portion to the second substrate portion,
wherein the foldable bridge portion comprises:
a coupling strip extending from the first substrate portion to the second substrate portion; and
a gap corresponding to a portion of the coupling strip and defined between the first and second substrate portions.

2. The foldable substrate as recited in claim 1, wherein the first and second substrate portions are from a same single semiconductor wafer substrate.

3. The foldable substrate as recited in claim 2, wherein the gap is cut from the single semiconductor wafer substrate.

4. The foldable substrate as recited in claim 2, wherein at least one of the first and second circuitry comprises at least one magnetic field sensor.

5. The foldable substrate as recited in claim 2, wherein the second circuitry comprises at least one contact pad accessible through an opening in the second insulating layer.

6. The foldable substrate as recited in claim 5, wherein the at least one contact pad is configured to accept solder.

7. The foldable substrate as recited in claim 1, wherein the coupling strip comprises a repeatably bendable material.

8. The foldable substrate as recited in claim 1, further comprising:
first circuitry disposed on the first surface; and
second circuitry disposed on the second surface.

9. The foldable substrate as recited in claim 8, wherein the foldable bridge portion electrically couples the first circuitry to the second circuitry.

10. The foldable substrate as recited in claim 8, wherein the first circuitry comprises:
a first magnetic field sensor to detect a magnetic field along a first direction; and
a second magnetic field sensor to detect the magnetic field along a second direction.

11. The foldable substrate as recited in claim 10, wherein:
the first and second magnetic field sensors are oriented, with respect to one another, such that the first and second directions are orthogonal to one another.

12. The foldable substrate as recited in claim 10, wherein the second circuitry comprises:
a third magnetic field sensor to detect the magnetic field along a third direction.

13. The foldable substrate as recited in claim 1, wherein the foldable bridge portion further comprises:
a first insulating layer extending from the first substrate portion to the second substrate portion,
wherein the coupling strip is disposed on a section of the first insulating layer.

14. The foldable substrate as recited in claim 13, wherein the foldable bridge portion further comprises:
a second insulating layer extending from the first substrate portion to the second substrate portion,
wherein the second insulation layer is disposed on a section of the coupling strip.

15. The foldable substrate as recited in claim 14, wherein each of the first insulating layer, the coupling strip and the second insulating layer comprises a repeatably bendable material.

16. The foldable substrate as recited in claim 13, wherein the foldable bridge portion further comprises:
at least one repeatably bendable metal strip.

17. The foldable substrate as recited in claim 16, wherein the at least one metal strip is disposed on a portion of the first insulating layer.

18. The foldable substrate as recited in claim 1, wherein the gap is defined by removing material from a starting substrate below the foldable bridge portion and wherein:
the gap in the starting substrate is created with opposing walls that are parallel to one another.

19. The foldable substrate as recited in claim 1, wherein the gap is defined by removing material from a starting substrate below the foldable bridge portion and wherein:
the gap in the starting substrate is created with opposing walls that are not parallel to one another.

20. A method of manufacturing a foldable substrate, comprising:
providing a wafer substrate having a wafer body portion, an upper surface and a lower surface;
defining a first substrate portion and a second substrate portion of the wafer substrate;
providing a foldable bridge portion extending from the first substrate portion to the second substrate portion; and
removing portions of the wafer body portion and creating a gap corresponding to at least a portion of the foldable bridge portion.

21. The method as recited in claim 20, wherein providing the foldable bridge portion further comprises:
providing at least one repeatably bendable metal strip extending from the first substrate portion to the second substrate portion.

22. The method as recited in claim 20, wherein removing portions of the wafer body comprises at least one of:
blade sawing;
laser sawing; and
masked etching.

23. The method as recited in claim 20, wherein providing the foldable bridge portion comprises:
providing a first coupling strip extending from the first substrate portion to the second substrate portion.

24. The method as recited in claim 23, wherein providing the foldable bridge portion comprises:
depositing a first passivation layer on a portion of the upper surface extending from the first substrate portion to the second substrate portion under the first coupling strip.

25. The method as recited in claim 23, wherein removing the portions of the wafer body comprises:
starting at the lower surface, removing material, and leaving the coupling strip substantially intact.

26. The method as recited in claim 25, wherein removing portions of the wafer body comprises:
removing wafer body material to create a gap having opposing walls that are parallel to one another.

27. The method as recited in claim 25, wherein removing portions of the wafer body comprises:
removing wafer body material to create a gap having opposing walls that are not parallel to one another.

28. The method as recited in claim 23, further comprising:
depositing at least one metal strip extending from the first substrate portion to the second substrate portion and substantially coplanar with the first coupling strip.

29. A foldable substrate comprising:
a first substrate portion having a first upper surface and a first lower surface;
a second substrate portion having a second upper surface and a second lower surface; and
a foldable portion coupling the first substrate portion to the second substrate portion,
wherein the foldable portion comprises a flexible material attached to the first and second lower surfaces.

30. The foldable substrate as recited in claim 29, wherein the flexible material is one of: a flexible film and a metal.

31. The foldable substrate as recited in claim 29, further comprising at least one of:
first circuitry disposed on the first upper surface; and
second circuitry disposed on the second upper surface.

32. The foldable substrate as recited in claim 29, further comprising:
a first magnetic field sensor to detect a magnetic field along a first direction disposed on the first substrate portion; and
a second magnetic field sensor to detect the magnetic field along a second direction disposed on the second substrate portion.

33. The foldable substrate as recited in claim 32, wherein:
the first and second magnetic field sensors are oriented, with respect to one another, such that the first and second directions are orthogonal to one another when the first and second substrate portions are arranged at a right angle to one another.

34. The foldable substrate as recited in claim 29, wherein the first and second substrate portions are defined by removing material from a starting substrate to create a gap in the starting substrate corresponding to the foldable portion.

35. The foldable substrate as recited in claim 34, wherein the gap in the starting substrate is created with opposing walls that are parallel to one another.

36. The foldable substrate as recited in claim 34, wherein the gap in the starting substrate is created with opposing walls that are not parallel to one another.

37. A method of manufacturing a foldable substrate, comprising:
providing a wafer having a body portion, an upper surface and a lower surface;
defining at least one circuitry-free zone extending in a direction from the upper surface down through the wafer body portion to the lower surface;
attaching a repeatably bendable material to the lower surface of the wafer at least under each at least one defined circuitry-free zone; and
removing part of the wafer body portion corresponding to the defined circuitry-free zone from the top surface of the wafer down to, but not removing, the repeatably bendable material.

38. The method as recited in claim 37, wherein removing each circuitry-free zone comprises at least one of:
blade sawing;
laser sawing; and
masked etching.

39. The method as recited in claim 37, wherein the repeatably bendable material is one of: a film and a metal.

40. The method as recited in claim 37, further comprising:
providing one or more devices on the upper surface of the wafer where no circuitry-free zone is defined.

41. The method as recited in claim 37, wherein removing each defined circuitry-free zone comprises removing less than all of the corresponding wafer body portion.

42. A three-axis magnetometer comprising:
a first substrate portion having first and second magnetic field sensors disposed thereon to detect a magnetic field along first and second directions, respectively, the first and second directions orthogonal to each other;
a second substrate portion having a third magnetic field sensor disposed thereon to detect the magnetic field along a third direction; and
a foldable bridge portion coupling the first substrate portion to the second substrate portion,
wherein the foldable bridge portion comprises:
a first insulating layer;
a coupling strip extending from the first substrate portion to the second substrate portion and disposed on a section of the first insulating layer;
a second insulating layer disposed on a section of the coupling strip; and
a gap defined between the first and second substrate portions.

43. The magnetometer as recited in claim 42, wherein each of the first and second substrate portions comprises a semiconductor material.

44. The magnetometer as recited in claim 42, wherein the foldable bridge portion further comprises:
at least one repeatably bendable metal strip.

45. The magnetometer as recited in claim 44, wherein the at least one metal strip is disposed on a portion of the first insulating layer.

46. The magnetometer as recited in claim 44, wherein the second substrate portion comprises at least one connection pad accessible through an opening in the second insulating layer.

47. The magnetometer as recited in claim 46, further comprising:
at least one via extending through the first substrate portion and coupled to the at least one connection pad.

48. The magnetometer as recited in claim 46, wherein the at least one connection pad is configured to accept solder.

49. The magnetometer as recited in claim 42, wherein:
the gap is created by removing material from a starting semiconductor substrate.

50. The three-axis magnetometer as recited in claim 49, wherein:
the gap in the starting substrate is created with opposing walls that are parallel to one another.

51. The three-axis magnetometer as recited in claim 49, wherein:
the gap in the starting substrate is created with opposing walls that are not parallel to one another.

52. The magnetometer as recited in claim 42, wherein:
each of the first insulating layer, the coupling strip and the second insulating layer extends from the first substrate portion to the second substrate portion.

53. The magnetometer as recited in claim 42, wherein each of the first insulating layer, the coupling strip and the second insulating layer comprises a repeatably bendable material.

54. The foldable substrate as recited in claim 1, further comprising:
a flexible material attached to a first lower surface of the first substrate portion and a second lower surface of the second substrate portion,
wherein the flexible material crosses the gap defined between the first and second substrate portions.

55. The method as recited in claim 20, further comprising:
providing a flexible material across the gap extending from a first lower surface of the first substrate portion to a second lower surface of the second substrate portion.
